(19) United States
(12) Patent Application Publication
(10) Pub. No.: US 2026/0276710 A1
(43) Pub. Date: Sep. 17, 2026

(54) SYSTEM AND METHOD OF CALCULATING BATTERY USAGE AND DEGRADATION

(71) Applicant: Volvo Car Corporation, Göteborg (SE)

(72) Inventors: Shoaib INAMDAR, Göteborg (SE); Didem AKKUS, Vastra Frölunda (SE); Emir KÖSE, Hovås (SE); Burak CALARGUN, Kungsbacka (SE)

(73) Assignee: Volvo Car Corporation, Göteborg (SE)

(21) Appl. No.: 19/077,275

(22) Filed: Mar. 12, 2025

(51) Int. Cl. G01R 31/367; B60L 3/12; B60L 55/00; B60L 58/16; G01R 31/392

(52) U.S. Cl. CPC G01R 31/367; B60L 3/12; B60L 58/16; G01R 31/392; B60L 55/00; B60L 2250/16

(57) ABSTRACT

A system is described. The system comprises: a memory, and a processor that is communicatively coupled to the memory, and the processor is operable to receive a first input comprising information on one or more grid supporting services; retrieve battery specifications of a battery and historical battery patterns; determine one or more baseline battery consumption patterns based on the first input, the battery specifications, and the historical battery usage data; simulate battery performance in relation to the one or more grid supporting services by incorporating change in frequency and intensity of charge and discharge cycles over time based on the one or more baseline battery consumption patterns; calculate battery usage and battery degradation during the simulation of the battery performance under the one or more grid supporting services; and generate a report upon calculating the battery usage and the battery degradation.

### FIELD OF THE INVENTION

The present disclosure relates generally to battery optimization in electric vehicles (EVs). More specifically, the present disclosure relates to a system and method of calculating battery usage and degradation caused by participation in grid supporting services.

### BACKGROUND

The growing integration of renewable energy sources has introduced challenges in maintaining power grid stability due to fluctuations in energy supply and demand. Grid services often require energy storage systems, including electric vehicle (EV) batteries, to charge and discharge energy to stabilize the grid. Participation in grid services places significant stress on said EV batteries due to the high frequency of charge and discharge cycles, leading to accelerated wear and reduced efficiency. Existing solutions do not provide accurate methods to analyze or predict the specific effects of grid services on energy storage system battery health and operational lifespan.

Therefore, there is a long-felt need for a system and method for calculating battery usage and degradation caused by participation in grid supporting services.

### SUMMARY

The following presents a summary to provide a basic understanding of one or more embodiments described herein. This summary is not intended to identify key or critical elements or delineate any scope of the different embodiments and/or any scope of the claims. The sole purpose of the summary is to present some concepts in a simplified form as a prelude to the more detailed description presented herein.

In one or more embodiments described herein, systems, devices, computer implemented methods, methods, apparatus and/or computer program products are presented that facilitate calculation of battery usage and degradation caused by participation in grid supporting services.

In an aspect, a system is described. The system comprises: a memory, and a processor that is communicatively coupled to the memory, wherein the processor is operable to receive a first input comprising information on one or more grid supporting services; retrieve battery specifications of a battery and historical battery patterns; determine one or more baseline battery consumption patterns based on the first input, the battery specifications, and the historical battery usage data; simulate battery performance in relation to the one or more grid supporting services by incorporating change in frequency and intensity of charge and discharge cycles over time based on the one or more baseline battery consumption patterns; calculate battery usage and battery degradation during the simulation of the battery performance under the one or more grid supporting services; and generate a report upon calculating the battery usage and the battery degradation.

In one aspect, a method is described. The method comprises: receiving a first input comprising information on one or more grid supporting services; retrieving battery specifications of a battery and historical battery usage data corresponding to the battery of a vehicle; determining one or more baseline battery consumption patterns based on the first input, the battery specifications, and the historical battery usage data; simulating battery performance in relation to the one or more grid supporting services by incorporating change in frequency and intensity of charge and discharge cycles over time based on the one or more baseline battery consumption patterns; calculating battery usage and battery degradation during the simulation of the battery performance under the one or more grid supporting services; and generating a report upon calculating the battery usage and the battery degradation.

In one aspect, a non-transitory computer readable storage medium is described. The non-transitory computer readable storage medium comprising a sequence of instructions, which when executed by a processor causes: receiving a first input comprising information on one or more grid supporting services; retrieving battery specifications of a battery and historical battery usage data corresponding to the battery of a vehicle; determining one or more baseline battery consumption patterns based on the first input, the battery specifications, and the historical battery usage data; simulating battery performance in relation to the one or more grid supporting services by incorporating change in frequency and intensity of charge and discharge cycles over time based on the one or more baseline battery consumption patterns; calculating battery usage and battery degradation during the simulation of the battery performance under the one or more grid supporting services; and generating a report upon calculating the battery usage and the battery degradation.

In an aspect, a vehicle is described. The vehicle comprises: a memory, and a processor that is communicatively coupled to the memory and the processor is operable to receive a first input comprising information on one or more grid supporting services; retrieve battery specifications of a battery and historical battery patterns; determine one or more baseline battery consumption patterns based on the first input, the battery specifications, and the historical battery usage data; simulate battery performance in relation to the one or more grid supporting services by incorporating change in frequency and intensity of charge and discharge cycles over time based on the one or more baseline battery consumption patterns; calculate battery usage and battery degradation during the simulation of the battery performance under the one or more grid supporting services; and generate a report upon calculating the battery usage and the battery degradation.

The methods and systems disclosed herein may be implemented in any means for achieving various aspects and may be executed in a form of a non-transitory machine-readable medium embodying a set of instructions that, when executed by a machine, causes the machine to perform any of the operations disclosed herein. Other features will be apparent from the accompanying drawings and from the detailed description that follows.

### BRIEF DESCRIPTION OF THE FIGURES

These and other aspects of the present disclosure will now be described in more detail, with reference to the appended drawings showing exemplary embodiments, in which:

FIG. 1 illustrates a system according to one or more embodiments.

FIG. 2 illustrates a method according to one or more embodiments.

FIG. 3 illustrates a non-transitory computer readable storage medium block diagram, according to one or more embodiments.

FIG. 4 illustrates a block diagram of a system according to one or more embodiments.

FIG. 5 illustrates a battery pack comprising an individual battery, according to one or more embodiments.

FIG. 6 illustrates a battery pack comprising a plurality of batteries, according to one or more embodiments.

FIG. 7 schematically shows a battery pack comprising a battery and a battery management system, according to one or more embodiments.

FIG. 8 illustrates a report displayed on an infotainment system of a vehicle, according to one or more embodiments.

FIG. 9 illustrates a bar chart comparing monetization value from participation in grid supporting services and battery replacement costs according to one or more embodiments.

FIG. 10 illustrates a line graph that depicts progression of battery degradation over time due to participation in grid supporting services, according to one or embodiments.

FIG. 11 illustrates a pie chart depicting the breakdown of the cost-benefit analysis associated with battery usage in grid supporting services according to one or more embodiments.

FIG. 12 illustrates a flowchart that depicts a process for analyzing an impact of grid supporting service participation on a battery of a vehicle according to one or embodiments.

FIG. 13 illustrates a block diagram of a machine learning model according to one or more embodiments.

FIG. 14A shows a structure of the neural network/machine learning model with a feedback loop.

FIG. 14B shows a structure of the neural network/machine learning model with reinforcement learning.

FIG. 15A shows a block diagram of the cyber security module in view of the system and server.

FIG. 15B shows an embodiment of the cyber security module.

FIG. 15C shows another embodiment of the cyber security module.

Other features of the present embodiments will be apparent from the accompanying drawings and from the detailed description that follows.

### DETAILED DESCRIPTION

For simplicity and clarity of illustration, the figures illustrate the general manner of construction. The description and figures may omit the descriptions and details of well-known features and techniques to avoid unnecessarily obscuring the present disclosure. The figures exaggerate the dimensions of some of the elements relative to other elements to help improve understanding of embodiments of the present disclosure. The same reference numeral in different figures denotes the same element.

Although the detailed description herein contains many specifics for the purpose of illustration, a person of ordinary skill in the art will appreciate that many variations and alterations to the details are considered to be included herein.

Accordingly, the embodiments herein are without any loss of generality to, and without imposing limitations upon, any claims set forth. The terminology used herein is for the purpose of describing particular embodiments only and is not limiting. Unless defined otherwise, all technical and scientific terms used herein have the same meaning as commonly understood by one with ordinary skill in the art to which this disclosure belongs.

Unless defined otherwise, all technical and scientific terms used herein have the same meaning as commonly understood by one with ordinary skill in the art.

As used herein, the articles “a” and “an” used herein refer to one or to more than one (i.e., to at least one) of the grammatical object of the article. By way of example, “an element” means one element or more than one element. Moreover, usage of articles “a” and “an” in the subject specification and annexed drawings construe to mean “one or more” unless specified otherwise or clear from context to mean a singular form.

As used herein, the terms “example” and/or “exemplary” mean serving as an example, instance, or illustration. For the avoidance of doubt, such examples do not limit the herein described subject matter. In addition, any aspect or design described herein as an “example” and/or “exemplary” is not necessarily preferred or advantageous over other aspects or designs, nor does it preclude equivalent exemplary structures and techniques known to those of ordinary skill in the art.

As used herein, the terms “first,” “second,” “third,” and the like in the description and in the claims, if any, distinguish between similar elements and do not necessarily describe a particular sequence or chronological order. The terms are interchangeable under appropriate circumstances such that the embodiments herein are, for example, capable of operation in sequences other than those illustrated or otherwise described herein. Furthermore, the terms “include,” “have,” and any variations thereof, cover a non-exclusive inclusion such that a process, method, system, article, device, or apparatus that comprises a list of elements is not necessarily limiting to those elements, but may include other elements not expressly listed or inherent to such process, method, system, article, device, or apparatus.

As used herein, the terms “left,” “right,” “front,” “back,” “top,” “bottom,” “over,” “under” and the like in the description and in the claims, if any, are for descriptive purposes and not necessarily for describing permanent relative positions. The terms so used are interchangeable under appropriate circumstances such that the embodiments of the apparatus, methods, and/or articles of manufacture described herein are, for example, capable of operation in other orientations than those illustrated or otherwise described herein.

No element act, or instruction used herein is critical or essential unless explicitly described as such. Furthermore, the term “set” includes items (e.g., related items, unrelated items, a combination of related items and unrelated items, etc.) and may be interchangeable with “one or more”. Where only one item is intended, the term “one” or similar language is used. Also, the terms “has,” “have,” “having,” or the like are open-ended terms. Further, the phrase “based on” means “based, at least in part, on” unless explicitly stated otherwise.

As used herein, the terms “system,” “device,” “unit,” and/or “module” refer to a different component, component portion, or component of the various levels of the order. However, other expressions that achieve the same purpose may replace the terms.

As used herein, the terms “couple,” “coupled,” “couples,” “coupling,” and the like refer to connecting two or more elements mechanically, electrically, and/or otherwise. Two or more electrical elements may be electrically coupled together, but not mechanically or otherwise coupled together. Coupling may be for any length of time, e.g., permanent, or semi-permanent or only for an instant. “Electrical coupling” includes electrical coupling of all types. The absence of the word “removably,” “removable,” and the like, near the word “coupled” and the like does not mean that the coupling, etc., in question is or is not removable.

As used herein, the term “or” means an inclusive “or” rather than an exclusive “or.” That is, unless specified otherwise, or clear from context. “X employs A or B” means any of the natural inclusive permutations. That is, if X employs A; X employs B; or X employs both A and B, then “X employs A or B” is satisfied under any of the foregoing instances.

As used herein, two or more elements or modules are “integral” or “integrated” if they operate functionally together. Two or more elements are “non-integral” if each element can operate functionally independently.

As used herein, the term “real-time” refers to operations conducted as soon as practically possible upon occurrence of a triggering event. A triggering event can include receipt of data necessary to execute a task or to otherwise process information. Because of delays inherent in transmission and/or in computing speeds, the term “real-time” encompasses operations that occur in “near” real-time or somewhat delayed from a triggering event. In a number of embodiments, “real-time” can mean real-time less a time delay for processing (e.g., determining) and/or transmitting data. The particular time delay can vary depending on the type and/or amount of the data, the processing speeds of the hardware, the transmission capability of the communication hardware, the transmission distance, etc. However, in many embodiments, the time delay can be less than approximately one second, two seconds, five seconds, or ten seconds.

As used herein, the term “approximately” can mean within a specified or unspecified range of the specified or unspecified stated value. In some embodiments, “approximately” can mean within plus or minus ten percent of the stated value. In other embodiments, “approximately” can mean within plus or minus five percent of the stated value. In further embodiments, “approximately” can mean within plus or minus three percent of the stated value. In yet other embodiments, “approximately” can mean within plus or minus one percent of the stated value.

Digital electronic circuitry, or in computer software, firmware, or hardware, including the structures disclosed in this specification and their structural equivalents, or in combinations of one or more of them may realize the implementations and all of the functional operations described in this specification. Implementations may be as one or more computer program products, i.e., one or more modules of computer program instructions encoded on a computer readable medium for execution by, or to control the operation of, data processing apparatus. The computer readable medium may be a machine-readable storage device, a machine-readable storage substrate, a memory device, a composition of matter affecting a machine-readable propagated signal, or a combination of one or more of them. The term “computing system” encompasses all apparatus, devices, and machines for processing data, including by way of example, a programmable processor, a computer, or multiple processors or computers. The apparatus may include, in addition to hardware, code that creates an execution environment for the computer program in question, e.g., code that constitutes processor firmware, a protocol stack, a database management system, an operating system, or a combination of one or more of them. A propagated signal is an artificially generated signal (e.g., a machine-generated electrical, optical, or electromagnetic signal) that encodes information for transmission to a suitable receiver apparatus.

The actual specialized control hardware or software code used to implement these systems and/or methods is not limiting to the implementations. Thus, any software and any hardware can implement the systems and/or methods based on the description herein without reference to specific software code.

A computer program (also known as a program, software, software application, script, or code) is written in any appropriate form of programming language, including compiled or interpreted languages. Any appropriate form, including a standalone program or a module, component, subroutine, or other unit suitable for use in a computing environment may deploy it. A computer program does not necessarily correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may execute on one computer or on multiple computers that are located at one site or distributed across multiple sites and interconnected by a communication network.

One or more programmable processors, executing one or more computer programs to perform functions by operating on input data and generating output, perform the processes and logic flows described in this specification. The processes and logic flows may also be performed by, and apparatus may also be implemented as, special purpose logic circuitry, for example, without limitation, a Field Programmable Gate Array (FPGA), an Application Specific Integrated Circuit (ASIC), Application Specific Standard Products (ASSPs), System-On-a-Chip (SOC) systems, Complex Programmable Logic Devices (CPLDs), etc.

Processors suitable for the execution of a computer program include, by way of example, both general and special purpose microprocessors, and any one or more processors of any appropriate kind of a digital computer. A processor will receive instructions and data from a read only memory or a random access memory or both. Elements of a computer can include a processor for performing instructions and one or more memory devices for storing instructions and data. A computer will also include, or is operatively coupled to receive data, transfer data or both, to/from one or more mass storage devices for storing data e.g., magnetic disks, magneto optical disks, optical disks, or solid-state disks. However, a computer need not have such devices. Moreover, another device, e.g., a mobile telephone, a personal digital assistant (PDA), a mobile audio player, a Global Positioning System (GPS) receiver, etc., may embed a computer. Computer readable media suitable for storing computer program instructions and data include all forms of nonvolatile memory, media and memory devices, including, by way of example, semiconductor memory devices (e.g., Erasable Programmable Read Only Memory (EPROM), Electronically Erasable Programmable Read Only Memory (EEPROM), and flash memory devices), magnetic disks (e.g., internal hard disks or removable disks), magneto optical disks (e.g. Compact Disc Read Only Memory (CD ROM) disks, Digital Versatile Disk-Read Only Memory (DVD-ROM) disks) and solid-state disks. Special purpose logic circuitry may supplement or incorporate the processor and the memory.

To provide for interaction with a user, a computer may have a display device, e.g., a Cathode Ray Tube (CRT) or Liquid Crystal Display (LCD) monitor, for displaying information to the user, and a keyboard and a pointing device, e.g., a mouse or a trackball, by which the user may provide input to the computer. Other kinds of devices provide for interaction with a user as well. For example, feedback to the user may be any appropriate form of sensory feedback, e.g., visual feedback, auditory feedback, or tactile feedback; and a computer may receive input from the user in any appropriate form, including acoustic, speech, or tactile input.

A computing system that includes a back-end component, e.g., a data server, or that includes a middleware component, e.g., an application server, or that includes a front-end component, e.g., a client computer having a graphical user interface or a Web browser through which a user may interact with an implementation, or any appropriate combination of one or more such back-end, middleware, or front-end components, may realize implementations described herein. Any appropriate form or medium of digital data communication, e.g., a communication network may interconnect the components of the system. Examples of communication networks include a Local Area Network (LAN) and a Wide Area Network (WAN), e.g., Intranet and Internet.

The computing system may include clients and servers. A client and server are remote from each other and typically interact through a communication network. The relationship of the client and server arises by virtue of computer programs running on the respective computers and having a client-server relationship with each other.

Embodiments may comprise or utilize a special purpose or general purpose computer including computer hardware. Embodiments within the scope of the present disclosure may also include physical and other computer readable media for carrying or storing computer executable instructions and/or data structures. Such computer readable media can be any media accessible by a general purpose or special purpose computer system. Computer readable media that store computer executable instructions are physical storage media. Computer readable media that carry computer executable instructions are transmission media. Thus, by way of example and not limitation, embodiments in the disclosure can comprise at least two distinct kinds of computer readable media: physical computer readable storage media and transmission computer readable media.

Although the present embodiments described herein are with reference to specific example embodiments it will be evident that various modifications and changes may be made to these embodiments without departing from the broader spirit and scope of the various embodiments. For example, hardware circuitry (e.g., Complementary Metal Oxide Semiconductor (CMOS) based logic circuitry), firmware, software (e.g., embodied in a non-transitory machine-readable medium), or any combination of hardware, firmware, and software may enable and operate the various devices, units, and modules described herein. For example, transistors, logic gates, and electrical circuits (e.g., Application Specific Integrated Circuit (ASIC) and/or Digital Signal Processor (DSP) circuit) may embody the various electrical structures and methods.

In addition, a non-transitory machine-readable medium and/or a system may embody the various operations, processes, and methods disclosed herein. Accordingly, the specification and drawings are illustrative rather than restrictive.

Physical computer readable storage media includes RAM, ROM, EEPROM, CD-ROM or other optical disk storage (such as CDs, DVDs, etc.), magnetic disk storage or other magnetic storage devices, solid-state disks or any other medium. They store desired program code in the form of computer executable instructions or data structures which can be accessed by a general purpose or special purpose computer.

As used herein, the term “network” refers to one or more data links that enable the transport of electronic data between computer systems and/or modules and/or other electronic devices. When a network or another communications connection (either hardwired, wireless, or a combination of hardwired or wireless) transfers or provides information to a computer, the computer properly views the connection as a transmission medium. A general purpose or special purpose computer access transmission media that can include a network and/or data links which carry desired program code in the form of computer executable instructions or data structures. The scope of computer readable media includes combinations of the above, that enable the transport of electronic data between computer systems and/or modules and/or other electronic devices. Further, upon reaching various computer system components, program code in the form of computer executable instructions or data structures can be transferred automatically from transmission computer readable media to physical computer readable storage media (or vice versa). For example, computer executable instructions or data structures received over a network or data link can be buffered in RAM within a Network Interface Controller (NIC), and then eventually transferred to computer system RAM and/or to less volatile computer readable physical storage media at a computer system. Thus, computer system components that also (or even primarily) utilize transmission media may include computer readable physical storage media.

Computer executable instructions comprise, for example, instructions and data which cause a general purpose computer, special purpose computer, or special purpose processing device to perform a certain function or group of functions. The computer executable instructions may be, for example, binary, intermediate format instructions such as assembly language, or even source code. Although the subject matter herein described is in a language specific to structural features and/or methodological acts, the described features or acts described do not limit the subject matter defined in the claims. Rather, the herein described features and acts are example forms of implementing the claims.

While this specification contains many specifics, these do not construe as limitations on the scope of the disclosure or of the claims, but as descriptions of features specific to particular implementations. A single implementation may implement certain features described in this specification in the context of separate implementations. Conversely, multiple implementations separately or in any suitable sub-combination may implement various features described herein in the context of a single implementation. Moreover, although features described herein as acting in certain combinations and even initially claimed as such, one or more features from a claimed combination may in some cases be excised from the combination, and the claimed combination may be directed to a sub-combination or variation of a sub-combination.

Similarly, while operations depicted herein in the drawings in a particular order to achieve desired results, this should not be understood as requiring that such operations be performed in the particular order shown or in sequential order or that all illustrated operations be performed, to achieve desirable results. In certain circumstances, multitasking and parallel processing may be advantageous. Moreover, the separation of various system components in the implementations should not be understood as requiring such separation in all implementations, and it should be understood that the described program components and systems may be integrated together in a single software product or packaged into multiple software products.

Even though particular combinations of features are recited in the claims and/or disclosed in the specification, these combinations are not intended to limit the disclosure of possible implementations. Other implementations are within the scope of the claims. For example, the actions recited in the claims may be performed in a different order and still achieve desirable results. In fact, many of these features may be combined in ways not specifically recited in the claims and/or disclosed in the specification. Although each dependent claim may directly depend on only one claim, the disclosure of possible implementations includes each dependent claim in combination with every other claim in the claim set.

Further, a computer system including one or more processors and computer readable media such as computer memory may practice the methods. In particular, one or more processors execute computer executable instructions, stored in the computer memory, to perform various functions such as the acts recited in the embodiments.

Those skilled in the art will appreciate that the invention may be practiced in network computing environments with many types of computer system configurations including personal computers, desktop computers, laptop computers, message processors, hand-held devices, multi-processor systems, microprocessor-based or programmable consumer electronics, network PCs, minicomputers, mainframe computers, mobile telephones, PDAs, pagers, routers, switches, etc. Distributed system environments where local and remote computer systems, which are linked (either by hardwired data links, wireless data links, or by a combination of hardwired and wireless data links) through a network, both perform tasks may also practice the invention. In a distributed system environment, program modules may be located in both local and remote memory storage devices.

The following terms and phrases, unless otherwise indicated, shall have the following meanings.

As used herein, the term “vehicle” as used herein refers to a thing used for transporting people or goods. Automobiles, cars, trucks, buses, etc., are examples of vehicles.

As used herein, the term “electric vehicle (EV)” refers to an automobile, as defined in 49 Code of Federal Regulations (CFR) 523.3, intended for highway use, powered by an electric motor that draws current from an on-vehicle energy storage device, such as a battery, which is rechargeable from an off-vehicle source, such as residential or public electric service or an on-vehicle fuel powered generator. The EV may be two or more wheeled vehicles manufactured for use primarily on public streets and roads. The EV may be referred to as an electric vehicle, an electric automobile, an electric road vehicle (ERV), a plug-in vehicle (PV), a plug-in vehicle (xEV), etc., and the xEV may be classified into a plug-in all-electric vehicle (BEV), a battery electric vehicle, a plug-in electric vehicle (PEV), a hybrid electric vehicle (HEV), a hybrid plug-in electric vehicle (HPEV), a plug-in hybrid electric vehicle (PHEV), etc.

As used herein, the term “plug-in electric vehicle (PEV)” refers to an Electric Vehicle that recharges the on-vehicle primary battery by connecting to the power grid.

As used herein, the term “plug-in vehicle (PV)” refers to an electric vehicle rechargeable through wireless charging from an electric vehicle supply equipment (EVSE) without using a physical plug or a physical socket.

As used herein, the term “heavy duty vehicle (HD Vehicle)” refers to any four-or-more wheeled vehicle as defined in 49 CFR 523.6 or 49 CFR 37.3 (bus).

As used herein, the term “light duty plug-in electric vehicle” refers to a three or four-wheeled vehicle propelled by an electric motor drawing current from a rechargeable storage battery or other energy devices for use primarily on public streets, roads and highways and rated at less than 4, 545 kg, (10,000 lbs.) gross vehicle weight.

As used herein, the term “battery pack” as used herein refers to a set of any number of identical batteries or individual cells of a battery. The “battery pack” may also refer to a set of non-identical batteries. The batteries in the battery pack may be configured in a series, parallel or a mixture of both to deliver the desired voltage, capacity, and/or power density.

As used herein, the term “grid supporting service” refers to the set of actions or functions provided by energy storage systems, such as electric vehicles (EVs) or stationary batteries, to enhance the stability, efficiency, and reliability of the electrical grid. These services are typically offered through two-way communication and energy exchange between the grid and the energy storage system.

As used herein, the term “battery specifications” refers to the set of technical and operational parameters that define the characteristics, performance, and operational limits of a battery. These specifications provide information for understanding and managing the battery's behavior in various applications, such as electric vehicles, grid supporting services, and energy storage systems.

As used herein, the term “historical battery usage data” refers to a collection of past operational records and performance metrics of a battery. This data provides detailed insights into the battery's usage patterns, environmental impacts, and performance trends, enabling accurate analysis, prediction, and optimization of future battery operations.

As used herein, the term “one or more baseline battery consumption patterns” refers to the standard or reference usage characteristics of a battery, established from historical data or simulations. These patterns represent the expected energy consumption and operational behavior under typical conditions, serving as a benchmark for assessing variations or the effects of specific applications, such as grid supporting services.

As used herein, the term “battery usage” refers to the amount of energy utilized by and supplied from a battery during its operation, as well as the associated charge-discharge cycles over time. The battery usage comprises metrics such as energy throughput, depth of discharge (DoD), and patterns of charging and discharging, which collectively describe how the battery has been employed in various applications or services.

As used herein, the term “battery degradation” refers to the progressive decline in the performance and capacity of a battery over time, resulting from factors such as repeated charge-discharge cycles, environmental conditions, and operational stress. Battery degradation is characterized by metrics such as reduced capacity, increased internal resistance, and diminished energy efficiency, impacting the overall lifespan and functionality of the battery.

As used herein, the term “Vehicle-to-Grid (V2G)” service refers to the bidirectional flow of energy between an electric vehicle (EV) and the electrical grid, enabling the vehicle's battery to act as a distributed energy resource. V2G services support grid stability and efficiency by allowing EVs to provide functions such as frequency regulation, peak load management, and energy storage. These services typically include charging the battery during low-demand periods and discharging energy back to the grid during high-demand or critical events.

As used herein, the term “Frequency Containment Reserve (FCR) service” refers to a grid supporting service aimed at stabilizing the nominal frequency of the electrical grid, which is typically 50 Hz or 60 Hz depending on the region. This frequency represents the rate of alternating current oscillations in the grid. FCR services automatically and in real-time adjust the power supply or demand to counteract deviations from the nominal frequency, ensuring grid stability and preventing disruptions caused by imbalances between electricity generation and consumption.

As used herein, the term “cost-benefit analysis” refers to a systematic evaluation method used to compare the financial costs and benefits associated with a particular activity, decision, or service. In the context of energy storage systems or grid supporting services, cost-benefit analysis assesses the economic trade-offs, considering factors such as operational costs, battery degradation impacts, energy savings, financial incentives, and revenue opportunities.

As used herein, the term “monetization value” refers to the financial value or revenue generated from leveraging a resource, service, or asset in a specific context. In the case of energy storage systems or electric vehicles (EVs), monetization value represents the economic return derived from participating in activities such as Vehicle-to-Grid (V2G) services, Frequency Containment Reserve (FCR) services, or other grid supporting applications.

As used herein, the term “total capacity” refers to the maximum amount of energy that a fully charged battery can store, typically measured in watt-hours (Wh) or ampere-hours (Ah). This value represents the battery's energy storage potential under ideal conditions.

As used herein, the term “State of Charge (SoC)” refers to the current energy level of a battery expressed as a percentage of its total capacity. It indicates how much energy remains available for use or discharge.

As used herein, the term “State of Health (SoH)” refers to a measure of a battery's condition relative to its original capacity and performance when new. SoH is expressed as a percentage and accounts for factors such as capacity fade, internal resistance, and degradation over time.

As used herein, the term “voltage range” refers to the range of voltages within which a battery operates safely and efficiently. This includes the minimum and maximum allowable voltages to prevent damage or unsafe conditions.

As used herein, the term “energy efficiency” refers to the ratio of the energy delivered by the battery to the energy used to charge it, expressed as a percentage. It reflects the battery's ability to store and discharge energy with minimal losses.

As used herein, the term “charge and discharge cycles” refers to the process by which a battery undergoes a full charge from a lower State of Charge (SoC) to its maximum capacity and then discharges to a specified lower SoC. A single cycle is defined as one complete round of charging and discharging, regardless of whether it occurs as a single event or as a series of partial charge and discharge events that cumulatively equates to a full cycle.

As used herein, the term “cycle count” refers to the number of complete charge and discharge cycles that a battery has undergone. A cycle is typically defined as a full discharge followed by a full charge, though partial cycles may also contribute proportionally.

As used herein, the term “age” refers to the time elapsed since the battery was manufactured or first used. Age can influence the battery's performance, capacity, and overall health due to chemical aging processes.

As used herein, the term “model” refers to the specific design, make, or version of a battery, defined by the manufacturer. It includes details about the battery's capacity, voltage, chemistry, and intended applications.

As used herein, the term “temperature range” refers to the range of ambient temperatures within which a battery can safely and efficiently operate.

As used herein, the term “chemistry type” refers to the specific electrochemical composition of a battery, such as lithium-ion, nickel-metal hydride, or lead-acid. The chemistry type determines the battery's characteristics, including capacity, voltage, cycle life, and safety.

As used herein, the term “average daily energy consumption” refers to the typical amount of energy utilized by a battery on a daily basis, measured in kilowatt-hours (kWh). This value reflects the battery's energy usage during regular operations, including driving and auxiliary loads.

As used herein, the term “frequency of discharge cycles” refers to the number of times the battery undergoes discharge events over a specific time period, such as daily or weekly. It indicates the regularity with which the battery is used to supply energy.

As used herein, the term “depth of discharge (DoD)” refers to the percentage of the total capacity of the battery that is discharged during each use.

As used herein, the term “charging frequency” refers to the number of times the battery is charged within a given time frame, such as per day or week.

As used herein, the term “charging durations” refers to the time intervals required to restore the energy levels of a battery to a specific state of charge (SoC). These durations can vary depending on factors such as the battery capacity, the power rating of the charging station, the initial SoC, and environmental conditions.

As used herein, the term “driving conditions” refers to the various operational scenarios that influence vehicle performance and energy consumption. These conditions comprise factors such as driving speed, terrain, traffic patterns, and the type of driving environment, comprising city driving, highway driving, hilly or mountainous terrain and stop-and-go traffic.

As used herein, the term “environmental factors” refers to the external conditions surrounding a vehicle's operation that can affect battery performance and energy usage. These factors include, but are not limited to temperature, humidity, weather conditions and altitude.

As used herein, the term “load patterns” refers to the variations in energy demand placed on a battery over time, based on the specific usage requirements of the connected system or device. Load patterns comprise factors such as the intensity, frequency, and duration of power drawn from the battery during operation.

As used herein, the term “battery degradation data” refers to information that quantifies the reduction in a battery's capacity, efficiency, or overall performance over time due to repeated charge and discharge cycles, environmental factors, or other operational stresses. This data comprises metrics such as capacity fade (percentage reduction in the maximum charge the battery can hold), resistance growth (increase in internal resistance affecting energy output), and changes in energy efficiency or State of Health (SoH).

As used herein, the term “usage patterns” refer to the specific manner in which a battery is utilized over time, including charging and discharging behaviors, energy throughput, depth of discharge (DoD), frequency and duration of use, and variations in power demand. Usage patterns comprise factors such as the timing and frequency of charging events, average and peak loads during operation, idle periods, and the consistency of power drawn during different applications, such as driving or grid supporting services.

As used herein, the term “capacity fade” refers to the gradual reduction in a battery's ability to store and deliver energy over time. The capacity fade occurs as a result of repeated charge and discharge cycles, environmental factors (such as temperature), and usage patterns that stress the battery.

As used herein, the term “infotainment system of a vehicle” or “infotainment unit” or “in-vehicle infotainment system” (IVI) as used herein refers to a combination of systems which are used to deliver entertainment and information. In an example, the information may be delivered to the driver and the passengers of a vehicle through audio/video interfaces, control elements like touch screen displays, button panel, voice commands, and more. Some of the main components of an in-vehicle infotainment systems are integrated head-unit, heads-up display, high-end Digital Signal Processors (DSPs), and Graphics Processing Units (GPUs) to support multiple displays, operating systems, Controller Area Network (CAN), Low-Voltage Differential Signaling (LVDS), and other network protocol support (as per the requirement), connectivity modules, automotive sensors integration, digital instrument cluster, etc.

As used herein, the term “vehicle computer system” refers to a system in automotive electronics that controls one or more of the electrical systems or subsystems in a vehicle. The computer executes a large number of different software functions in the powertrain, chassis, driver assistance, and infotainment domains, etc., that are executed on separate control units. The vehicle computer system may be communicatively coupled with an external device of a user.

As used herein, the term “interactive display” refers to a user interface embedded in or mounted on a wall-mounted unit that allows users to interact with and control various functions or settings related to a system.

As used herein, the term “user device” refers to any electronic or digital equipment used by an individual to interact with or control a system. The user device can be a smartphone, tablet, laptop or desktop computer and smartwatch.

As used herein, the term “communication” refers to the transmission of information and/or data from one point to another. Communication may be by means of electromagnetic waves. It is also a flow of information from one point, known as the source, to another, the receiver. Communication comprises one of the following: transmitting data, instructions, and information or a combination of data, instructions, and information. Communication happens between any two communication systems or communicating units. The term “in communication with” may refer to any coupling, connection, or interaction using electrical signals to exchange information or data, using any system, hardware, software, protocol, or format, regardless of whether the exchange occurs wirelessly or over a wired connection. The term “communication” includes systems that combine other more specific types of communication, such as V2I (Vehicle-to-Infrastructure), V2I (Vehicle-to-Infrastructure), V2N (Vehicle-to-Network), V2V (Vehicle-to-Vehicle), V2P (Vehicle-to-Pedestrian), V2D (Vehicle-to-Device) and V2G (Vehicle-to-Grid) and Vehicle-to-Everything (V2X) communication. V2X communication is the transmission of information from a vehicle to any entity that may affect the vehicle, and vice versa. The main motivations for developing V2X are occupant safety, road safety, traffic efficiency and energy efficiency. Depending on the underlying technology employed, there are two types of V2X communication technologies: cellular networks and other technologies that support direct device-to-device communication (such as Dedicated Short-Range Communication (DSRC), Port Community System (PCS), Bluetooth®, Wi-Fi®, etc.). Further, the emergency communication apparatus is configured on a computer with the communication function and is connected for bidirectional communication with the on-vehicle emergency report apparatus by a communication line through a radio station and a communication network such as a public telephone network or by satellite communication through a communication satellite. The emergency communication apparatus is adapted to communicate, through the communication network, with communication terminals including a road management office, a police station, a fire department, and a hospital. The emergency communication apparatus can also be connected online with the communication terminals of the persons or vehicles concerned, associated with the occupant or vehicle, and the driver or vehicle receiving the service of the emergency-reporting vehicle.

The terms “non-transitory computer readable medium” and “computer readable medium” include a single medium or multiple media such as a centralized or distributed database, and/or associated caches and servers that store one or more sets of instructions. Further, the terms “non-transitory computer readable medium” and “computer readable medium” include any tangible medium that is capable of storing, encoding, or carrying a set of instructions for execution by a processor that, for example, when executed, cause a system to perform any one or more of the methods or operations disclosed herein. As used herein, the term “computer readable medium” is expressly defined to include any type of computer readable storage device and/or storage disk and to exclude propagating signals.

The term, “handshaking” refers to an exchange of predetermined signals between agents connected by a communications channel to assure each that it is connected to the other (and not to an imposter). This may also include the use of passwords and codes by an operator. Handshaking signals are transmitted back and forth over a communications network to establish a valid connection between two stations. A hardware handshake uses dedicated wires such as the request-to-send (RTS) and clear-to-send (CTS) lines in an RS-232 serial transmission. A software handshake sends codes such as “synchronize” (SYN) and “acknowledge” (ACK) in a TCP/IP transmission.

The term “in communication with” as used herein, refers to any coupling, connection, or interaction using electrical signals to exchange information or data, using any system, hardware, software, protocol, or format, regardless of whether the exchange occurs wirelessly or over a wired connection.

As used herein, the term “network” may include the Internet, a local area network, a wide area network, or combinations thereof. The network may include one or more networks or communication systems, such as the Internet, the telephone system, satellite networks, cable television networks, and various other private and public networks. In addition, the connections may include wired connections (such as wires, cables, fiber optic lines, etc.), wireless connections, or combinations thereof. Furthermore, although not shown, other computers, systems, devices, and networks may also be connected to the network. Network refers to any set of devices or subsystems connected by links joining (directly or indirectly) a set of terminal nodes sharing resources located on or provided by network nodes. The computers use common communication protocols over digital interconnections to communicate with each other. For example, subsystems may comprise the cloud. Cloud refers to servers that are accessed over the Internet, and the software and databases that run on those servers.

The embodiments described herein can be directed to one or more of a system, a method, an apparatus, and/or a computer program product at any possible technical detail level of integration. The computer program product can include a computer readable storage medium (or media) having computer readable program instructions thereon for causing a processor to carry out aspects of the one or more embodiments described herein. The computer readable storage medium can be a tangible device that can retain and store instructions for use by an instruction execution device. For example, the computer readable storage medium can be, but is not limited to, an electronic storage device, a magnetic storage device, an optical storage device, an electromagnetic storage device, a superconducting storage device, and/or any suitable combination of the foregoing. A non-exhaustive list of more specific examples of the computer readable storage medium can also include the following: a portable computer diskette, a hard disk, a random access memory (RAM), a read only memory (ROM), an erasable programmable read only memory (EPROM or Flash memory), a static random access memory (SRAM), a portable compact disc read only memory (CD-ROM), a digital versatile disk (DVD), a memory stick, a floppy disk, a mechanically encoded device such as punch-cards or raised structures in a groove having instructions recorded thereon and/or any suitable combination of the foregoing. A computer readable storage medium, as used herein, does not construe transitory signals per se, such as radio waves and/or other freely propagating electromagnetic waves, electromagnetic waves propagating through a waveguide and/or other transmission media (e.g., light pulses passing through a fiber optic cable), and/or electrical signals transmitted through a wire.

Computer readable program instructions described herein are downloadable to respective computing/processing devices from a computer readable storage medium and/or to an external computer or external storage device via a network, for example, the Internet, a local area network, a wide area network and/or a wireless network. The network can comprise copper transmission cables, optical transmission fibers, wireless transmission, routers, firewalls, switches, gateway computers, and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of the one or more embodiments described herein can be assembler instructions, instruction-set-architecture (ISA) instructions, machine instructions, machine dependent instructions, microcode, firmware instructions, state-setting data, configuration data for integrated circuitry, and/or source code and/or object code written in any combination of one or more programming languages, including an object oriented programming language such as Smalltalk, C++ or the like, and/or procedural programming languages, such as the “C” programming language and/or similar programming languages. The computer readable program instructions can execute entirely on a computer, partly on a computer, as a standalone software package, partly on a computer and/or partly on a remote computer or entirely on the remote computer and/or server. In the latter scenario, the remote computer can be connected to a computer through any type of network, including a local area network (LAN) and/or a wide area network (WAN), and/or the connection can be made to an external computer (for example, through the Internet using an Internet Service Provider). In one or more embodiments, electronic circuitry including, for example, programmable logic circuitry, field programmable gate arrays (FPGA), and/or programmable logic arrays (PLA) can execute the computer readable program instructions by utilizing state information of the computer readable program instructions to personalize the electronic circuitry, in order to perform aspects of the one or more embodiments described herein.

Aspects of the one or more embodiments described herein are described with reference to flowchart illustrations and/or block diagrams of methods, apparatus (systems), and computer program products according to one or more embodiments described herein. Each block of the flowchart illustrations and/or block diagrams, and combinations of blocks in the flowchart illustrations and/or block diagrams, can be implemented by computer readable program instructions. These computer readable program instructions can be provided to a processor of a general purpose computer, special purpose computer and/or other programmable data processing apparatus to produce a machine, such that the instructions, which execute via the processor of the computer or other programmable data processing apparatus, can create means for implementing the functions/acts specified in the flowchart and/or block diagram block or blocks. These computer readable program instructions can also be stored in a computer readable storage medium that can direct a computer, a programmable data processing apparatus and/or other devices to function in a particular manner, such that the computer readable storage medium having instructions stored therein can comprise an article of manufacture including instructions which can implement aspects of the function/act specified in the flowchart and/or block diagram block or blocks. The computer readable program instructions can also be loaded onto a computer, other programmable data processing apparatus and/or other device to cause a series of operational acts to be performed on the computer, other programmable apparatus and/or other device to produce a computer implemented process, such that the instructions which execute on the computer, other programmable apparatus and/or other device implement the functions/acts specified in the flowchart and/or block diagram block or blocks.

The flowcharts and block diagrams in the figures illustrate the architecture, functionality and/or operation of possible implementations of systems, computer-implementable methods and/or computer program products according to one or more embodiments described herein. In this regard, each block in the flowchart or block diagrams can represent a module, segment and/or portion of instructions, which comprises one or more executable instructions for implementing the specified logical function(s). In one or more alternative implementations, the functions noted in the blocks can occur out of the order noted in the Figures. For example, two blocks shown in succession can be executed substantially concurrently, and/or the blocks can sometimes be executed in the reverse order, depending upon the functionality involved. It will also be noted that each block of the block diagrams and/or flowchart illustration, and/or combinations of blocks in the block diagrams and/or flowchart illustration, can be implemented by special purpose hardware-based systems that can perform the specified functions and/or acts and/or carry out one or more combinations of special purpose hardware and/or computer instructions.

While the subject matter described herein is in the general context of computer executable instructions of a computer program product that runs on a computer and/or computers, those skilled in the art will recognize that the one or more embodiments herein also can be implemented in combination with one or more other program modules. Program modules include routines, programs, components, data structures, and/or the like that perform particular tasks and/or implement particular abstract data types. Moreover, other computer system configurations, including single-processor and/or multi-processor computer systems, mini-computing devices, mainframe computers, as well as computers, hand-held computing devices (e.g., PDA, phone), microprocessor-based or programmable consumer and/or industrial electronics and/or the like can practice the herein described computer implemented methods. Distributed computing environments, in which remote processing devices linked through a communications network perform tasks, can also practice the illustrated aspects. However, standalone computers can practice one or more, if not all, aspects of the one or more embodiments described herein. In a distributed computing environment, program modules can be located in both local and remote memory storage devices.

As used in this application, the terms “component,” “system,” “platform,” “interface,” and/or the like, can refer to and/or can include a computer-related entity or an entity related to an operational machine with one or more specific functionalities. The entities described herein can be either hardware, a combination of hardware and software, software, or software in execution. For example, a component can be, but is not limited to being, a process running on a processor, a processor, an object, an executable, a thread of execution, a program and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system and/or across a network such as the Internet with other systems via the signal). As another example, a component can be an apparatus with specific functionality provided by mechanical parts operated by electric or electronic circuitry, which is operated by a software and/or firmware application executed by a processor. In such a case, the processor can be internal and/or external to the apparatus and can execute at least a part of the software and/or firmware application. As yet another example, a component can be an apparatus that provides specific functionality through electronic components without mechanical parts, where the electronic components can include a processor and/or other means to execute software and/or firmware that confers at least in part the functionality of the electronic components. In an aspect, a component can emulate an electronic component via a virtual machine, e.g., within a cloud computing system.

As it is employed in the subject specification, the term “processor” can refer to any computing processing unit and/or device comprising, but not limited to, single-core processors; single-processors with software multi-thread execution capability; multi-core processors; multi-core processors with software multi-thread execution capability; multi-core processors with hardware multi-thread technology; parallel platforms; and/or parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, and/or any combination thereof designed to perform the functions described herein. Further, processors can exploit nano-scale architectures such as, but not limited to, molecular based transistors, switches and/or gates, in order to optimize space usage and/or to enhance performance of related equipment. A combination of computing processing units can implement a processor.

Herein, terms such as “store,” “storage,” “data store,” data storage,” “database,” and any other information storage component relevant to operation and functionality of a component refer to “memory components,” entities embodied in a “memory,” or components comprising a memory. Memory and/or memory components described herein can be either volatile memory or nonvolatile memory or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory, and/or nonvolatile random access memory (RAM) (e.g., ferroelectric RAM (FeRAM). Volatile memory can include RAM, which can function as external cache memory, for example. By way of illustration and not limitation, RAM can be available in many forms such as synchronous RAM (SRAM), dynamic RAM (DRAM), synchronous DRAM (SDRAM), double data rate SDRAM (DDR SDRAM), enhanced SDRAM (ESDRAM), Synch link DRAM (SLDRAM), direct Rambus RAM (DRRAM), direct Rambus dynamic RAM (DRDRAM) and/or Rambus dynamic RAM (RDRAM). Additionally, the described memory components of systems and/or computer implemented methods herein include, without being limited to including, these and/or any other suitable types of memory.

The embodiments described herein include mere examples of systems and computer implemented methods. It is, of course, not possible to describe every conceivable combination of components and/or computer implemented methods for purposes of describing the one or more embodiments, but one of ordinary skill in the art can recognize that many further combinations and/or permutations of the one or more embodiments are possible. Furthermore, to the extent that the terms “includes,” “has,” “possesses,” and the like are used in the detailed description, claims, appendices and/or drawings such terms are intended to be inclusive in a manner similar to the term “comprising” as “comprising” is interpreted when employed as a transitional word in a claim.

The descriptions of the one or more embodiments are for purposes of illustration but are not exhaustive or limiting to the embodiments described herein. Many modifications and variations will be apparent to those of ordinary skill in the art without departing from the scope and spirit of the described embodiments. The terminology used herein best explains the principles of the embodiments, the practical application and/or technical improvement over technologies found in the marketplace, and/or to enable others of ordinary skill in the art to understand the embodiments described herein.

Business problem: As renewable energy integration grows, power grids increasingly depend on energy storage systems, including electric vehicle (EV) batteries, to provide grid stabilization services. However, participation in grid supporting services exposes EV batteries to frequent and intense charge-discharge cycles, accelerating degradation and reducing operational efficiency. This creates challenges for vehicle operators in predicting battery lifespan, assessing financial feasibility, and optimizing the use of EV batteries for grid supporting services, potentially leading to increased degradation and reduced reliability of the EV batteries.

Business solution: The present system enables analysis of battery performance for vehicles participating in grid supporting services. The present system retrieves relevant battery specifications and historical usage data and uses a machine learning model to establish baseline battery consumption patterns. By simulating battery performance under varying conditions of charge and discharge cycles, the system calculates battery usage and degradation over time. The present system provides vehicle operators and energy providers with actionable insights to optimize battery utilization, minimize wear, and make informed decisions about participating in grid supporting services.

Technical problem: Current systems lack the capability to predict and analyze the impact of frequent charge-discharge cycles on EV batteries when participating in grid stabilization services. These systems fail to account for battery degradation under varying operational conditions, leading to an incomplete understanding of battery health and efficiency. Additionally, the absence of reliable methods to simulate battery performance in grid supporting services makes it difficult to provide accurate insights for optimizing battery usage and minimizing wear.

Technical Solution: The present system processes a first input comprising information about a grid supporting service and retrieves battery specifications and historical usage data of the vehicle's battery. Using a machine learning model, it determines baseline battery consumption patterns based on the input data. The system performs simulations of battery performance under the grid supporting service, accounting for changes in the frequency and intensity of charge-discharge cycles over time. The present system then calculates battery usage and degradation based on the simulation results. The present system provides technical insights into battery performance, enabling optimization of battery operations under grid supporting services.

Technical Result: The present system provides the evaluation of battery performance under grid supporting services by simulating the effects of varying charge and discharge cycles over time. The present system determines baseline battery consumption patterns and calculates battery usage and degradation with precision. This ensures better prediction of battery lifespan and operational efficiency. The integration of machine learning and simulation reduces errors in battery performance assessment, enabling effective battery management. Furthermore, the system enables informed decision-making regarding the use of batteries in grid supporting services, thereby enhancing reliability and reducing battery wear.

### Technical Details Specific to Technical Result

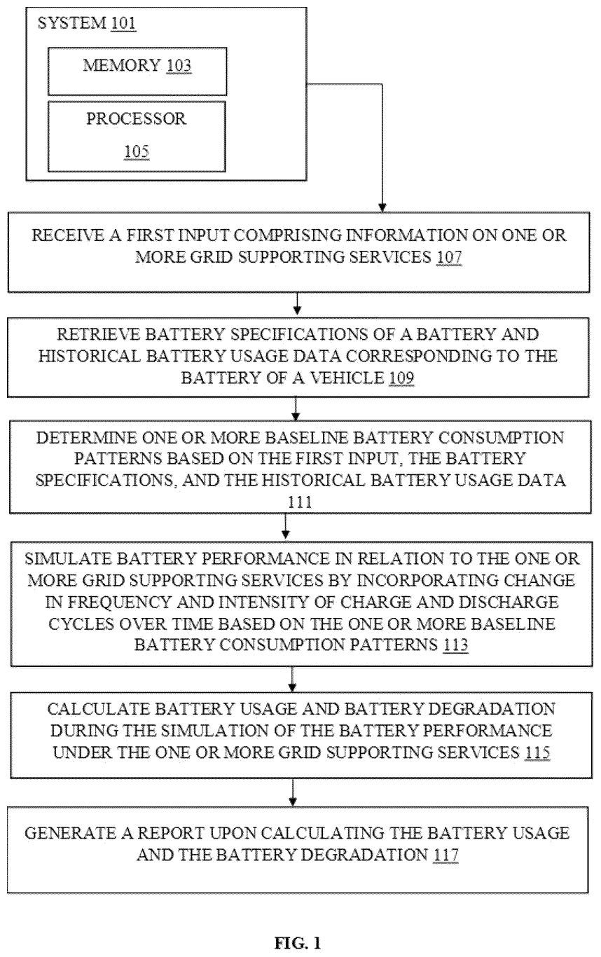

In an aspect, a system is described. As an example, FIG. 1 illustrates a system 101, according to one or more embodiments. The system 101 comprises: a memory 103, and a processor 105 that is communicatively coupled to the memory 103 and the processor is operable to receive a first input comprising information on one or more grid supporting services (at step 107); retrieve battery specifications of a battery and historical battery patterns (at step 109); determine one or more baseline battery consumption patterns based on the first input, the battery specifications, and the historical battery usage data (at step 111); simulate battery performance in relation to the one or more grid supporting services by incorporating change in frequency and intensity of charge and discharge cycles over time based on the one or more baseline battery consumption patterns (at step 113); calculate battery usage and battery degradation during the simulation of the battery performance under the one or more grid supporting services (at step 115); and generate a report upon calculating the battery usage and the battery degradation (at step 117).

In one embodiment, the one or more grid supporting services are selected from at least one of a Vehicle-to-Grid (V2G) service and a Frequency Containment Reserve (FCR) service.

In one embodiment, the first input comprises information on frequency of participation in a Frequency Containment Reserve (FCR) service, expected duration of each session, user-defined preferences and operational parameters related to the battery and the vehicle.

In one embodiment, the battery specifications comprise total capacity, State of Charge (SOC), State of Health (SOH), voltage range, energy efficiency, cycle count, age, model, temperature range, and chemistry type of the battery.

In one embodiment, the historical battery usage data comprises charge-discharge cycles, energy throughput, State of Charge (SOC) patterns, environmental factors, charging behavior, load patterns, and battery degradation data.

In one embodiment, the one or more baseline battery consumption patterns comprise average daily energy consumption, frequency, and depth of discharge cycles, charging frequency, charging durations, and variations in energy usage across one or more driving conditions and environmental factors.

In one embodiment, the processor 105 is operable to calculate the battery usage by performing a battery usage analysis that comprises determining energy throughput, charge and discharge cycles, depth of discharge (DoD), and operational conditions of the battery during participation in the one or more grid supporting services.

In one embodiment, the processor 105 is operable to calculate the battery degradation by performing a battery degradation analysis that comprises determining capacity fade, internal resistance growth, depth of discharge, charge and discharge cycle count, and temperature variations over time of the battery during operation under the one or more grid supporting services.

In one embodiment, the one or more baseline battery consumption patterns are determined using a machine learning model. In one embodiment, the processor 105 is operable to determine a range of one or more inputs that comprise the first input, the battery specifications, and the historical battery usage data and determine that the range of the one or more inputs is in a predefined range. In one embodiment, the predefined range is dynamically adjusted based on characteristics of the one or more inputs being analyzed. In one embodiment, the characteristics of the one or more inputs comprises a source of the one or more inputs and historical patterns of previous analysis of the battery performance to enhance accuracy of determining the range of the one or more inputs.

In one embodiment, the processor 105 is operable to provide a first iteration of training to the machine learning model based on the one or more inputs.

In one embodiment, the processor 105 is operable to perform, using the machine learning model, a cost-benefit analysis that corresponds to the one or more grid supporting services by comparing monetization value for participating the vehicle in the one or more grid supporting services with costs associated with at least one of increased wear, replacement, and maintenance of the battery.

In one embodiment, the processor 105 is operable to generate the report based on the simulation of battery performance, a battery usage analysis, a battery degradation analysis and the cost-benefit analysis corresponding to the one or more grid supporting services. In one embodiment, the report comprises a summary of the battery usage analysis, the battery degradation analysis, and the cost-benefit analysis corresponding to the one or more grid supporting services. The summary of the battery usage analysis may comprise information on energy throughput, charge-discharge cycles, depth of discharge (DoD), and operational conditions of the battery during the participation in the one or more grid supporting services. The summary of the battery degradation analysis may comprise information on capacity fade, internal resistance growth, depth of discharge, charge and discharge cycle count, and temperature variations over time of the battery during operation under the one or more grid supporting services. The summary of the cost-benefit analysis may comprise financial gains, battery wear costs, replacement costs, maintenance costs and a net benefit calculation.

In one embodiment, the report comprises an analysis of the battery usage and the battery degradation calculated from the simulation of the battery performance under the one or more grid supporting services, and the cost-benefit analysis comprises financial gains and associated costs of participating in the one or more grid supporting services.

In one embodiment, the processor 105 is operable to display the report corresponding to the one or more grid supporting services to the user. In one embodiment, the processor 105 is operable to send the report to a Frequency Control Reserve (FCR) service and one or more external entities that comprise energy management systems, smart grid operators, and cloud storage providers.

In one embodiment, the processor 105 is operable to receive adjustment of the first input from the user. In one embodiment, the first input is received from the user. In one embodiment, the first input is received from the vehicle. In one embodiment, the first input is received from a charging station.

In one embodiment, the battery specifications and the historical battery usage data are retrieved from an onboard diagnostic system of the vehicle.

In one embodiment, the battery specifications and the historical battery usage data are retrieved from a database.

In one embodiment, the processor 105 is operable to receive the battery specifications from at least one of the user and a battery management system of the vehicle.

In one embodiment, the processor 105 is operable to receive a feedback from the user in response to the displayed report.

In one embodiment, the processor 105 is operable to modify the simulation of the battery performance based on the feedback received from the user.

In one embodiment, the processor 105 is operable to continuously receive real-time battery health data from the battery management system of the vehicle.

In one embodiment, the processor 105 is operable to receive an output derived from the simulation of the battery performance under the one or more grid supporting services and the real-time battery health data and provide the output as a feedback to the machine learning model to provide a second iteration of training.

In one embodiment, the machine learning model refines the simulation of the battery performance based on the second iteration of training.

In one embodiment, the system 101 is integrated within the vehicle.

In one embodiment, the system 101 is integrated in a server.

How Technical Solution is a Technological Advancement: The technical solution represents a significant advancement using a machine learning module to simulate and predict battery performance in grid supporting services. The technical solution enhances the accuracy of determining battery degradation under varying charge and discharge cycles, thereby improving the battery health and operational efficiency. This capability provides informed decision-making regarding battery usage and maintenance. Additionally, by integrating historical data with real-time simulations, the technical solution enables maintenance and optimization of battery usage, thereby extending battery life and improving the overall effectiveness of grid supporting services.

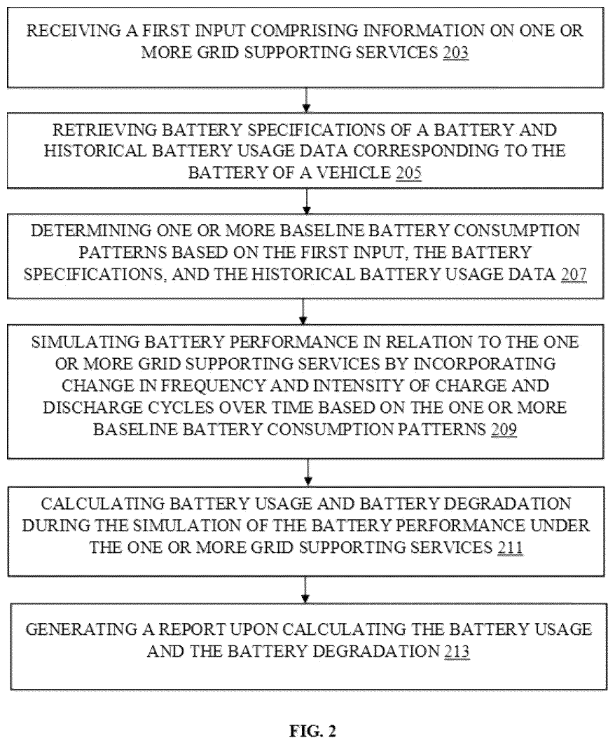

In one aspect, a method is described. As an example, FIG. 2 illustrates a method according to one or more embodiments. The method comprises the following technical steps: receiving a first input comprising information on one or more grid supporting services (at step 203); retrieving battery specifications of a battery and historical battery usage data corresponding to the battery of a vehicle (at step 205); determining one or more baseline battery consumption patterns based on the first input, the battery specifications, and the historical battery usage data (at step 207); simulating battery performance in relation to the one or more grid supporting services by incorporating change in frequency and intensity of charge and discharge cycles over time based on the one or more baseline battery consumption patterns (at step 209); calculating battery usage and battery degradation during the simulation of the battery performance under the one or more grid supporting services (at step 211); and generating a report upon calculating the battery usage and the battery degradation (at step 213).

In one embodiment, the one or more grid supporting services are selected from at least one of a Vehicle-to-Grid (V2G) service and a Frequency Containment Reserve (FCR) service. In one embodiment, the one or more baseline battery consumption patterns are determined using a machine learning model.

In one embodiment, the method further comprises: providing a first iteration of training to the machine learning model based on one or more inputs that comprise the first input, the battery specifications, and the historical battery usage data. In one embodiment, the method further comprises: determining a range of the one or more inputs and determining that the range of the one or more inputs is in a predefined range. In one embodiment, the predefined range is dynamically adjusted based on characteristics of the one or more inputs being analyzed.

In one embodiment, the method further comprises: performing, using the machine learning model, a cost-benefit analysis that corresponds to the one or more grid supporting services by comparing monetization value of participating the vehicle in the one or more grid supporting services with costs associated with at least one of increased wear, replacement, and maintenance of the battery.

In one embodiment, the method further comprises: generating the report based on the simulation of battery performance, a battery usage analysis, a battery degradation analysis and the cost-benefit analysis corresponding to the one or more grid supporting services.

In one embodiment, the report comprises a summary of the battery usage analysis, the battery degradation analysis, and the cost-benefit analysis corresponding to the one or more grid supporting services.

In one embodiment, the method further comprises: displaying the report corresponding to the one or more grid supporting services to the user. In one embodiment, the method further comprises: receiving a feedback from the user in response to the displayed report. In one embodiment, the method further comprises: modifying the simulation of the battery performance based on the feedback received from the user.

In one embodiment, the method further comprises: sending the report to the Frequency Control Reserve (FCR) service and one or more external entities that comprise energy management systems, smart grid operators, and cloud storage providers.

In one embodiment, the method further comprises: continuously receiving real-time battery health data from a battery management system of the vehicle.

In one embodiment, the method further comprises: receiving an output derived from the simulation of the battery performance under the one or more grid supporting services and the real-time battery health data and providing the output as a feedback to the machine learning model to provide a second iteration of training.

In one embodiment, the machine learning model refines the calculation of the battery usage, and the battery degradation based on the second iteration of training.

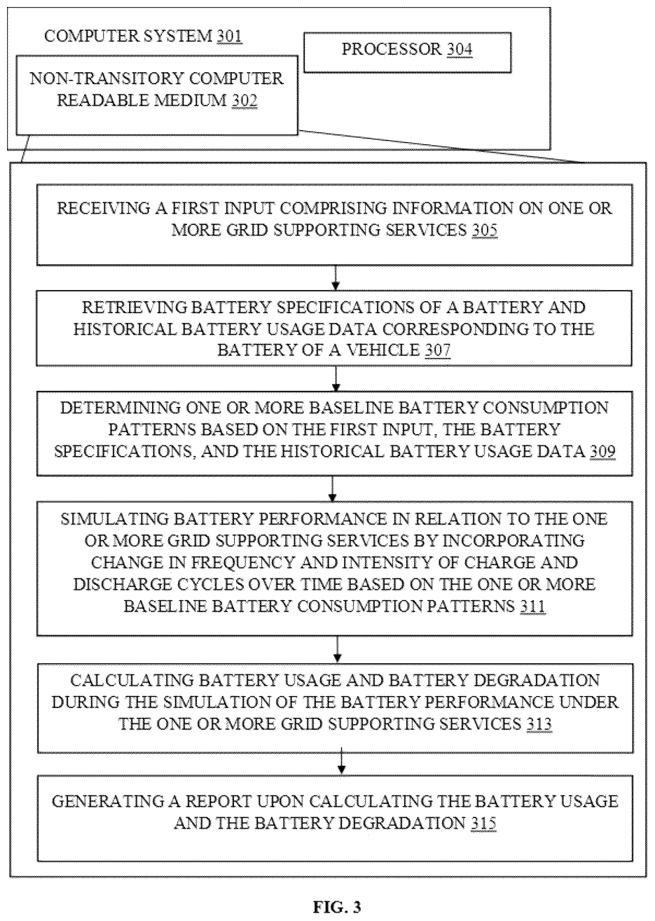

As an example, FIG. 3 illustrates a non-transitory computer readable storage medium, according to one or more embodiments. According to an embodiment, disclosed is a computer system 301 comprising the non-transitory computer readable storage medium 302 having stored thereon instructions executable by a processor 304 to perform operations comprising: receiving a first input comprising information on one or more grid supporting services (at step 305); retrieving battery specifications of a battery and historical battery usage data corresponding to the battery of a vehicle (at step 307); determining one or more baseline battery consumption patterns based on the first input, the battery specifications, and the historical battery usage data (at step 309); simulating battery performance in relation to the one or more grid supporting services by incorporating change in frequency and intensity of charge and discharge cycles over time based on the one or more baseline battery consumption patterns (at step 311); calculating battery usage and battery degradation during the simulation of the battery performance under the one or more grid supporting services (at step 313); and generating a report upon calculating the battery usage and the battery degradation (at step 315).

In one embodiment, the one or more grid supporting services are selected from at least one of a Vehicle-to-Grid (V2G) service and a Frequency Containment Reserve (FCR) service.

In one embodiment, the one or more baseline battery consumption patterns are determined using a machine learning model.

In one embodiment, the non-transitory computer readable storage medium 302 further causes: providing a first iteration of training to the machine learning model based on one or more inputs that comprise the first input, the battery specifications, and the historical battery usage data. In one embodiment, the non-transitory computer readable storage medium 302 further causes: determining a range of the one or more inputs and determining that the range of the one or more inputs is in a predefined range.

In one embodiment, the predefined range is dynamically adjusted based on characteristics of the one or more inputs being analyzed.

In one embodiment, the non-transitory computer readable storage medium 302 further causes: performing, using the machine learning model, a cost-benefit analysis that corresponds to the one or more grid supporting services by comparing monetization value of participating the vehicle in the one or more grid supporting services with costs associated with at least one of increased wear, replacement, and maintenance of the battery.

In one embodiment, the non-transitory computer readable storage medium 302 further causes: generating the report based on the simulation of battery performance, a battery usage analysis, a battery degradation analysis and the cost-benefit analysis corresponding to the one or more grid supporting services.

In one embodiment, the report comprises a summary of the battery usage analysis, the battery degradation analysis, and the cost-benefit analysis corresponding to the one or more grid supporting services.

In one embodiment, the non-transitory computer readable storage medium 302 further causes: displaying the report corresponding to the one or more grid supporting services to the user.

In one embodiment, the non-transitory computer readable storage medium 302 further causes: receiving a feedback from the user in response to the displayed report. In one embodiment, the non-transitory computer readable storage medium 302 further causes: modifying the simulation of the battery performance based on the feedback received from the user.

In one embodiment, the non-transitory computer readable storage medium 302 further causes: sending the report to the Frequency Control Reserve (FCR) service and one or more external entities that comprise energy management systems, smart grid operators, and cloud storage providers.

In one embodiment, the non-transitory computer readable storage medium 302 further causes: continuously receiving real-time battery health data from a battery management system of the vehicle.

In one embodiment, the non-transitory computer readable storage medium 302 further causes: receiving an output derived from the simulation of the battery performance under the one or more grid supporting services and the real-time battery health data and providing the output as a feedback to the machine learning model to provide a second iteration of training.

In one embodiment, the machine learning model refines the calculation of the battery usage, and the battery degradation based on the second iteration of training.

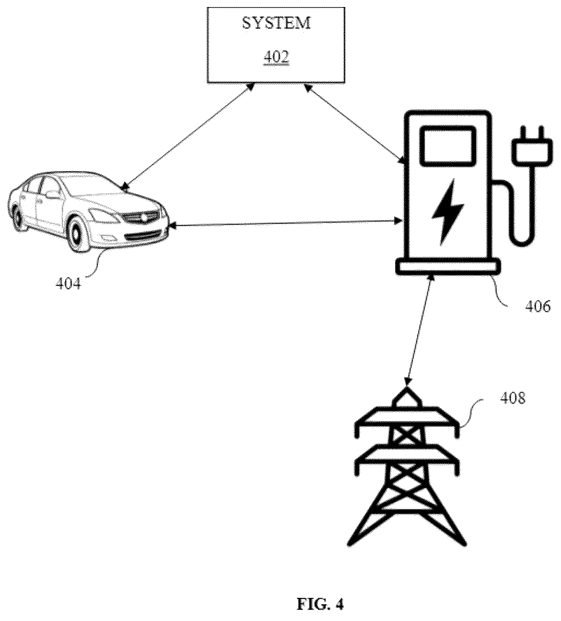

As an example, FIG. 4 illustrates a block diagram of a system 402 according to one or more embodiments. The block diagram comprises the system 402, a vehicle 404, a charging station 406 and a grid 408. The vehicle 404 is equipped with a battery management system (BMS) that provides real-time battery health data. The charging station 406 serves as an interface for energy exchange, enabling participation in grid supporting services. The grid 408 represents the energy network, which requires support for frequency containment and stability, for which the EV battery serves as a resource.

The system 402 receives the first input comprising information on the grid supporting services. The first input comprises information on frequency of participation in a Frequency Containment Reserve (FCR) service, expected duration of each session, user-defined preferences and operational parameters related to the battery and the vehicle 404.

In an embodiment, the system 402 may receive the first input from a user. In another embodiment, the system 402 may receive the first input from the vehicle 404. In another embodiment, the system 402 may receive the first input from the charging station 406.

The system 402 is designed to retrieve battery specifications, historical battery usage data, and real-time battery health data. The battery specifications may comprise total capacity, State of Charge (SOC), State of Health (SOH), voltage range, energy efficiency, cycle count, age, model, temperature range, and chemistry type of the battery. The historical battery usage data may comprise charge-discharge cycles, energy throughput, State of Charge (SOC) patterns, environmental factors, charging behavior, load patterns, and battery degradation data.

In one embodiment, the battery specifications and the historical battery usage data are retrieved from an onboard diagnostic system of the vehicle 404. In one embodiment, the battery specifications and the historical battery usage data are retrieved from a database. The system 402 may receive the battery specifications from at least one of the user and the battery management system of the vehicle 404.

The system 402 is operable to validate the accuracy of one or more inputs, which comprise the first input, the battery specifications, and the historical battery usage data, by determining whether the range of the one or more inputs falls within a predefined range. The predefined range is dynamically adjusted based on the characteristics of the one or more inputs being analyzed. These characteristics comprise the source of the one or more inputs and historical patterns of previous analyses of battery performance. This dynamic adjustment enhances the accuracy of determining the range of the one or more inputs and ensures the reliability of subsequent analyses.

During preprocessing, the system 402 is operable to normalize and preprocess the one or more inputs, employing techniques such as scaling and handling missing values. In one embodiment, scaling data ensures that numerical values from different sources, such as the first input, the battery specifications, and the historical battery usage data, are adjusted to a uniform scale for comparison and analysis. The system 402 may utilize methods such as min-max normalization, which rescales the inputs to a defined range, typically [0,1], or z-score standardization, which transforms the data to have a mean of 0 and a standard deviation of 1. For example, the depth of discharge cycles from historical battery usage data may be scaled to align with other metrics like average energy consumption from the battery specifications, enabling consistent analysis across all inputs.

The system 402 is further operable to identify missing values in the one or more inputs to ensure completeness and data integrity. In one embodiment, missing values in the inputs, such as gaps in historical usage data or incomplete battery specification details, are handled using techniques such as mean/mode imputation or predictive imputation. In mean/mode imputation, missing entries are replaced with the mean or mode of the available data for that specific metric, such as replacing missing charge duration values with the average duration. For more complex or non-random missing patterns, the system 402 may apply advanced methods, such as regression-based imputation or machine learning algorithms. In one embodiment, missing historical data on energy usage under specific conditions can be predicted using a regression model, trained on related parameters such as charge frequency and DoD cycles.

After validating and preprocessing the one or more inputs, the system 402 is operable to determine one or more baseline battery consumption patterns using a machine learning model. The one or more baseline battery consumption serve as a base line, defining the typical energy usage and degradation experienced by the battery under normal conditions. The one or more baseline battery consumption patterns comprise metrics such as average daily energy consumption, frequency and depth of discharge (DoD) cycles, charging frequency and durations, and variations in energy usage across diverse driving conditions and environmental factors.

To determine these baseline patterns, the system 402 applies machine learning techniques in conjunction with traditional statistical analysis. The system 402 may utilize supervised learning algorithms, such as regression models, to predict the battery usage based on the historical battery usage data and the battery specifications. In one embodiment, the regression model is trained on the historical battery usage data, comprising the vehicle's energy consumption, charge and discharge cycles, and other relevant parameters, to identify patterns and trends.

Additionally, the system 402 may employ clustering algorithms, such as k-means clustering or DBSCAN (Density-Based Spatial Clustering of Applications with Noise), to segment historical data into distinct groups representing different driving behaviors and environmental conditions. In one embodiment, the system 402 can classify data based on patterns such as urban driving, which often involves frequent stops and starts, or highway driving, characterized by more consistent speeds.

The system 402 may further apply time series forecasting models such as ARIMA (AutoRegressive Integrated Moving Average) or LSTM (Long Short-Term Memory) networks to capture temporal trends in energy usage and degradation. These models can identify seasonality and long-term trends, helping to predict how the battery will behave under normal usage over time.

By combining these machine learning techniques with statistical analysis, the system 402 determines the baseline battery consumption patterns, which reflect typical battery performance under varying conditions. These baseline patterns serve as the base line for simulating battery performance under the grid supporting services and assessing the impacts of participation in the grid supporting services on battery health and efficiency.

Upon determining the one or more baseline battery consumption patterns, the system 402 simulates battery performance in relation to the grid supporting services by incorporating changes in the frequency and intensity of charge and discharge cycles over time. This simulation is performed based on the baseline battery consumption patterns and accounts for the unique characteristics of the grid supporting services which comprise frequent, rapid charging and discharging cycles. To model this, the system 402 integrates the baseline patterns of energy usage, discharge depth, and charging frequency into the simulation. The system 402 then applies a dynamic simulation model, such as a system dynamics model or a battery charge/discharge model, to simulate how the battery's performance will be affected by these changing conditions. The system 402 adjusts the parameters based on the characteristics of the grid supporting services, factoring in the intensity and frequency of the charge and discharge cycles induced by the grid supporting services, and the corresponding environmental and operational conditions, such as temperature or driving patterns. For example, in an FCR scenario, where the battery may quickly discharge and recharge to stabilize the grid, the system 402 increases the frequency and intensity of the charge and discharge cycles compared to typical usage. The simulation model may employ stochastic techniques to account for the variability and unpredictability of the grid, such as sudden frequency deviations or load changes, which could affect the battery's performance and efficiency. In one embodiment, Monte Carlo simulations could be used to model these uncertainties and predict a range of possible outcomes, allowing the system 402 to assess the impact of varying grid conditions over time.

Further, the system 402 can integrate real-time data, if available, into the simulation to further refine the battery performance model. For example, incorporating live grid frequency data or the battery's real-time state of charge (SOC) could enhance the accuracy of the simulation. The system 402 may comprise feedback loops where the battery's performance under simulated grid conditions influences future simulations, allowing the system 402 to adapt dynamically to changing conditions and optimize battery usage for the grid supporting services. By simulating the battery performance under these conditions, the system 402 can predict the effects of participating in the grid supporting services, such as the potential for increased battery wear and reduction in efficiency.

After simulating the battery performance under the grid supporting services, the system 402 calculates the battery usage and the battery degradation based on the results of the simulation. The system 402 calculates the battery usage by performing a battery usage analysis that comprises determining energy throughput, charge and discharge cycles, depth of discharge (DoD), and operational conditions of the battery during participation in the one or more grid supporting services. In one embodiment, energy throughput is determined as the total energy that flows in and out of the battery over a specific period. This comprises monitoring charging and discharging power, typically measured in kilowatts (kW), and multiplying it by the duration (hours) to determine the energy in kilowatt-hours (kWh). By summing the energy values across all charge-discharge events, the system 402 estimates the cumulative energy throughput during grid supporting service participation. In one embodiment, this data is obtained from at least one of the battery management systems (BMS) logs or through simulation models that replicate real-time charge and discharge behavior.

In one embodiment, charge-discharge cycles are determined by analyzing changes in the battery's State of Charge (SOC). In one embodiment, a complete cycle is defined as a 100% swing in SOC, such as charging from 30% to 80% SOC and discharging back to 30%. In one embodiment, partial cycles, such as charging from 30% to 50%, are combined to calculate an equivalent full cycle. The system 402 aggregates SOC data over the service period to estimate the total number of charge-discharge cycles.

In one embodiment, Depth of Discharge (DoD) measures the extent to which the battery is discharged relative to its total capacity. For each charge-discharge cycle, DoD is calculated as the difference between the initial and final SOC, expressed as a percentage of the battery's full capacity. For example, if the SOC drops from 80% to 30% during a cycle, the DoD is 50%. The system 402 averages DoD values across multiple cycles to evaluate the battery's operating patterns during participation in the grid supporting service.

In one embodiment, the system 402 logs temperature readings from one or more sensors to monitor range and peaks during operation. In one embodiment, voltage and current values are measured during charging and discharging to assess power flow and identify high-stress conditions, such as rapid current changes or charging at high voltage. These factors are aggregated to understand how operational conditions correlate with battery usage and degradation trends.

The system 402 calculates the battery degradation by performing a battery degradation analysis that comprises determining capacity fade, internal resistance growth, depth of discharge, charge and discharge cycle count, and temperature variations over time of the battery during operation under the one or more grid supporting services.

In one embodiment, the capacity fade is determined by monitoring the reduction in the battery's maximum charge-holding capacity over time. The system 402 compares the battery's initial capacity to its current capacity after repeated charging and discharging cycles. For example, if a battery initially held 50 kWh of energy and now holds only 45 kWh, the capacity fade is 10%. This degradation is calculated using historical charge-discharge data and periodic updates from the battery management system (BMS).

In one embodiment, the system 402 calculates internal resistance by analyzing voltage drops during current flow in charge-discharge events. Over time, as internal resistance increases, more energy is lost as heat, reducing efficiency. For example, the system 402 may observe a 20% increase in internal resistance after 500 cycles, indicating wear.

In one embodiment, Depth of Discharge (DoD) is also evaluated as a contributing factor to degradation. Higher or inconsistent DoD levels can accelerate wear on battery cells. By analyzing the average and peak DoD values during grid supporting service participation, the system 402 identifies stress patterns that may exacerbate degradation. For example, repeatedly discharging the battery to 90% DoD could result in faster degradation compared to operations with a 50% DoD.

In one embodiment, the charge-discharge cycle count is tracked as the cumulative number of equivalent full cycles the battery has undergone. Each cycle contributes to battery wear, and the system 402 uses this count to correlate degradation rates with usage intensity. For example, a battery completing 1000 cycles under moderate conditions may experience less degradation than one completing the same cycles under high DoD or extreme temperatures.

In one embodiment, the system 402 logs temperature data from sensors embedded in the battery to track fluctuations during operation. High temperatures accelerate chemical degradation, while low temperatures reduce performance and increase resistance. By analyzing these variations, the system 402 identifies operating conditions that may shorten the battery's lifespan. For example, a battery consistently operating at 40° C. might degrade faster than one maintained within the ideal range of 20° C. to 30° C.

To perform the cost-benefit analysis that corresponds to the grid supporting services, the system 402 utilizes the machine learning model that compares the monetization value for participating in the grid supporting services with the costs associated with battery wear, replacement, and maintenance. In one embodiment, the system 402 employs regression analysis and predictive modeling techniques to calculate the relationship between battery degradation and its impact on costs. These techniques can assess historical data and simulate future performance under varying grid supporting service conditions to predict battery wear over time.

The monetization value for participating in the grid supporting services are calculated based on the energy exchange (charge and discharge cycles) between the battery of the vehicle 404 and the grid 408. The system 402 uses historical data on the financial compensation received for grid supporting services provided to the grid 408, and the factors such as market price fluctuations, to predict potential future earnings. In one embodiment, time series forecasting models, such as autoregressive integrated moving average (ARIMA) or long short-term memory (LSTM) networks, can be used to predict the future market value of energy transactions and estimate the financial gains that can be achieved by participating in these grid supporting services.

The system 402 calculates the costs associated with battery wear due to participation in the grid supporting services. The system 402 uses predictive models, such as regression analysis or support vector machines (SVM), to predict the increase in battery degradation due to the high frequency of charging and discharging. These models can factor in the intensity of participation in the grid supporting services to estimate how much faster the battery will degrade compared to normal use. The system 402 further integrates cost estimation models, which factor in the depreciation rates of batteries, the average cost of replacement, and the expected maintenance costs over time. In one embodiment, Monte Carlo simulations or decision tree algorithms can be employed to simulate various scenarios and determine the potential impact of different participation levels in the grid supporting services on the overall battery costs. These models generate a range of possible outcomes, allowing the system 402 to assess the financial risks and rewards associated with participating in the grid supporting services.

The system 402 generates the report based on the simulation of battery performance, a battery usage analysis, a battery degradation analysis and the cost-benefit analysis corresponding to the one or more grid supporting services. The report comprises a summary of the battery usage analysis, the battery degradation analysis, and the cost-benefit analysis corresponding to the one or more grid supporting services. The summary of the battery usage comprises information about how the battery is utilized during participation in the grid supporting service. The summary comprises energy throughput, which quantifies the total energy delivered by the battery over a specific period. For example, if the battery consistently delivers 50 kWh daily for a month, the energy throughput is 1500 kWh. This metric enables assessing the intensity of battery usage. The charge-discharge cycles comprise information about the number of full or partial charge-discharge events completed by the battery, indicating its operational frequency. For example, if the battery undergoes 100 cycles in a month, the analysis captures this data. Depth of Discharge (DoD) comprises the information about the proportion of the battery capacity used in each cycle; for example, if the battery is discharged from 100% to 20%, the DoD is 80%. In one embodiment, operational conditions comprise the information about the environmental and system parameters affecting the battery, such as operating temperatures or charging behavior during grid supporting service participation. For example, a report may show that the battery was consistently exposed to high DoD during peak grid demand, potentially accelerating wear.

In one embodiment, the summary of the battery degradation analysis comprises information about identifying how the battery's health deteriorates over time under operational stress. The summary of the battery degradation analysis comprises capacity fade, which measures the reduction in the battery's ability to store energy. For example, if the battery originally stored 100 kWh but now stores 90 kWh, a 10% capacity fade is reported. In one embodiment, internal resistance growth examines how resistance within the battery increases, reducing its power delivery efficiency. For example, the system 402 may identify a 20% increase in internal resistance after 500 cycles. The summary also comprises depth of discharge, linking high or inconsistent DoD patterns to accelerated wear. Additionally, the charge-discharge cycle count reveals the cumulative operational load, such as a total of 2000 cycles over three years. In one embodiment, the temperature variations over time highlight the battery's exposure to extreme conditions. For example, the report may show that prolonged and sustained exposure to temperatures above 40° C. resulted in significant capacity fade and increased internal resistance.

In one embodiment, the summary of the cost-benefit analysis comprises information about the financial perspective on the trade-offs of participating in grid supporting services. The summary of the cost-benefit analysis comprises the financial gains, such as revenue from services such as vehicle-to-grid (V2G) or frequency containment reserve (FCR). For example, a vehicle may earn $500 monthly by participating in FCR services. However, these gains are compared against battery wear costs, which estimate the monetary equivalent of accelerated degradation due to service participation. For example, if a 10% capacity fade requires a $2000 battery replacement sooner than expected, this cost is factored in. Additionally, replacement costs evaluate the expenses incurred from degraded or worn-out batteries, such as the cost of purchasing and installing a new battery. In one embodiment, maintenance costs account for ongoing expenses, such as repairs or recalibration required due to intensive usage. The analysis concludes with a net benefit calculation, balancing all financial factors to determine profitability. For example, if financial gains total $5000 over a year but wear and replacement costs amount to $3000, the net benefit is $2000.

In one embodiment, the report may comprise recommendations that provide actionable insights based on the battery usage analysis, the battery degradation analysis and the cost-benefit analysis. These recommendations may comprise guidance on whether or not to continue participating in the grid supporting service, such as V2G or FCR, and, if beneficial, specify the optimal frequency and duration of participation to maximize financial gains while minimizing battery wear. For example, the report might recommend participating only during off-peak hours to reduce battery degradation. Additionally, the recommendations may include maintenance schedules based on the battery's health and performance trends, such as scheduling a battery health check within a specific timeframe due to increased internal resistance. The report might also suggest specific charging and discharging practices, such as limiting the depth of discharge (DoD) to a certain percentage to optimize battery health and lifespan. Further, it could advise on managing operational conditions, such as temperature control, to prevent accelerated battery degradation, with suggestions such as avoiding high-temperature operations beyond a specified threshold.

The system 402 may display the report corresponding to the one or more grid supporting services to the user. The report can be displayed on the vehicle's onboard interface, such as a touchscreen dashboard, enabling the user to access the information while inside the vehicle. In one embodiment, the report can be accessed through a mobile application, allowing the user to review the details remotely on their smartphones or tablets. In one embodiment, the system 402 provides access to the report via a web portal, where the user can log in to view the analysis, including downloadable or printable format.

The system 402 may use visualization techniques such as bar charts, line graphs, and pie charts to display the report to the user. The system 402 may receive a feedback from the user regarding the report. For example, the user may provide inputs on the accuracy and relevance of the recommendations or indicate preferences for specific operational strategies, such as prioritizing battery health over financial gains or vice versa. Based on this feedback, the system 402 can adjust its simulation models or refine its cost-benefit analysis to align with the user's priorities. Additionally, the feedback may comprise suggestions for modifying the frequency or duration of participation in grid supporting services, preferences for visualizing specific data points in the report, or concerns about maintenance schedules. In one embodiment, the system 402 sends the report to the Frequency Control Reserve (FCR) service and one or more external entities that comprise energy management systems, smart grid operators, and cloud storage providers.

The system 402 may transmit the report through a network. The network may be wired (e.g., Ethernet) or wireless (e.g., Wi-Fi, LTE, 5G). In one embodiment, upon transmission, the Frequency Control Reserve (FCR) service analyzes the report to optimize grid-balancing decisions, ensuring that the battery complies with regulatory and operational standards for frequency stabilization. In one embodiment, energy Management Systems (EMS) may use the report to make strategic decisions regarding energy dispatch, peak shaving, and demand response, thereby optimizing energy usage across connected systems. In one embodiment, smart grid operators may assess the report to evaluate the health and reliability of the battery for grid services, enabling efficient energy flow management. In one embodiment, the report is stored in cloud storage or other repositories for future analysis and compliance reporting.

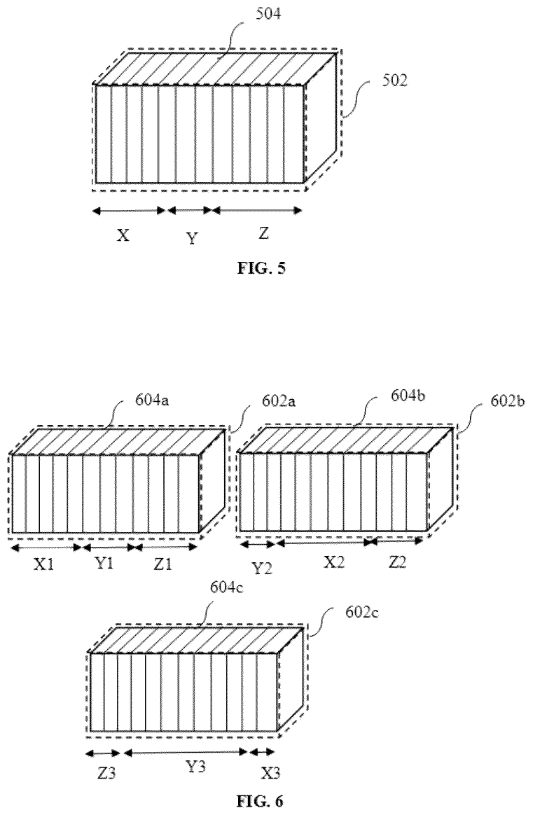

As an example, FIG. 5 illustrates a battery pack 502 comprising an individual battery, according to one or more embodiments. The battery pack 502 may be the battery within the charging station. In one embodiment, the battery pack 502 is within a vehicle. The battery pack 502 within the charging station is stationary and large enough to supply power to charge multiple vehicles simultaneously. The battery within the charging station is huge when compared to the battery within the electric vehicles. The battery pack 502 herein comprises an individual battery. The battery comprises a plurality of cells 504. The battery pack comprises a first portion X, a second portion Y, and a third portion Z. The first portion X may comprise a first plurality of cells among the plurality of cells of the battery. The second portion Y may comprise a second plurality of cells among the plurality of cells of the battery. The third portion Z may comprise a third plurality of cells among the plurality of cells of the battery.

The first portion X, the second portion Y, and the third portion Z may be categorized based on the state-of-health information at the respective portions. The first portion X may comprise a first state-of-health. The second portion Y may comprise a second state-of-health. The third portion Z may comprise a third state-of-health. In an embodiment, the first portion may refer to a portion of the battery having degraded cells. The second portion may refer to a portion of the battery having healthy cells. The third portion may refer to a portion of the battery having moderate degraded cells. The processor may be configured to detect the state of charge of the battery pack 502 having at least one of healthy cells, degraded cells, and moderate degraded cells.

As an example, FIG. 6 illustrates a battery pack comprising a plurality of batteries, according to one or more embodiments. The battery pack herein comprises a first battery 602a, a second battery 602b, and a third battery 602c. The first battery 602a may comprise a plurality of first cells 604a. The second battery 602b may comprise a plurality of second cells 604b. The third battery 602c may comprise a plurality of third cells 604c. Each battery of the battery pack is connected electrically to get charged. The charging station charges each battery of the battery pack. The charging station may charge each battery of the battery pack through at least one of randomly, serially, and parallelly.

The charging station may charge at least one of a first portion X, a second portion Y, and a third portion Z of the battery pack. The first portion X of the battery pack refers to degraded cells from one or more batteries of the battery pack (X=X1+X2+X3). The second portion Y of the battery pack refers to healthy cells from one or more batteries of the battery pack (Y=Y1+Y2+Y3). The third portion Z of the battery pack refers to moderate degraded cells from one or more batteries of the battery pack (Z=Z1+Z2+Z3). Healthy cells may be contiguous or non-contiguously located within the same battery. Similarly, degraded, and moderate degraded cells may be contiguous or non-contiguously located within the same battery. In one embodiment, the charging station may charge in combination of degraded cells, healthy cells, and moderate degraded cells from the one or more batteries.

The charging station is configured to map the battery pack based on the state-of-health information. In an embodiment, the charging station maps at least one of the degraded cells, the healthy cells, and the moderate degraded cells of the battery pack. The charging station, upon performing mapping the battery pack, computes the state of charge considering the state-of-health information.

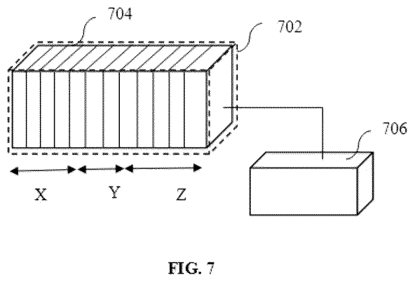

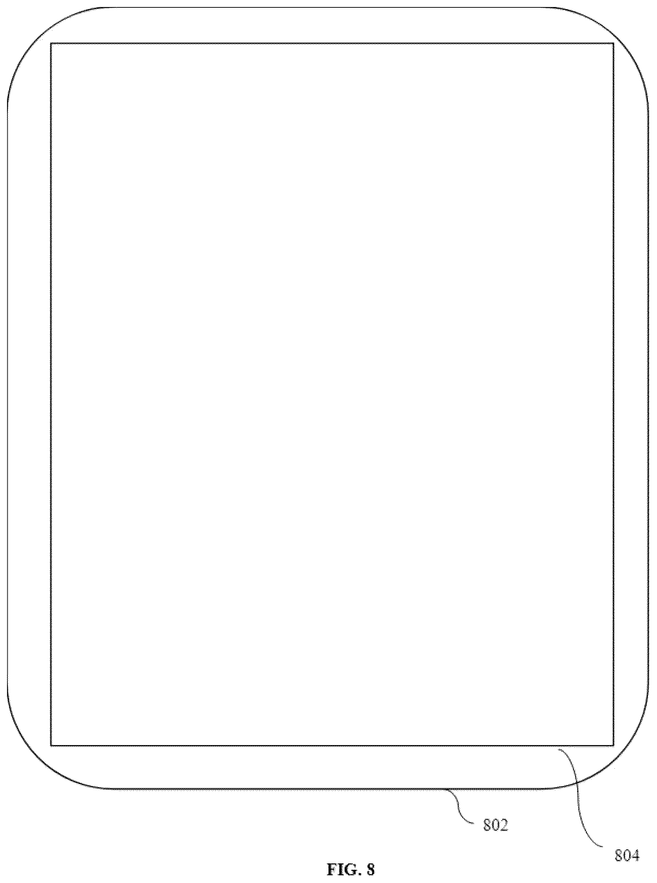

As an example, FIG. 7 schematically shows a battery pack comprising a battery 702 and a battery management system 706, according to one or more embodiments. The battery 702 in turn comprises a plurality of cells 704. The battery management system 706 may include a microprocessor, microcontroller, programmable digital signal processor, or another programmable device. The battery management system 706 may also or alternatively comprise an application specific integrated circuit, a programmable gate array or programmable array logic, a programmable logic device or a digital signal processor. Where the battery management system 706 comprises a programmable device such as the microprocessor, microcontroller or programmable digital signal processor mentioned above, the processor may also comprise computer executable code which controls the operation of the programmable device. In an embodiment, the battery management system 706 resides within an electric vehicle. The battery management system 706 determines the state of charge (SoC) of the battery pack and communicates to the charging station via a vehicle computer system.

As an example, FIG. 8 illustrates a report 804 displayed on an infotainment system 802 of a vehicle, according to one or more embodiments. The report 804 provides a summary of the vehicle's battery usage, degradation, and cost-benefit analysis of participating in the grid supporting services, such as Frequency Containment Reserve (FCR).

The grid supporting service section of the report 804 comprises details about the service type (FCR), expected frequency of cycles (200 cycles per month), and the intensity of cycles (high, involving deep discharge cycles). The battery simulation section comprises the vehicle's battery performance under FCR participation, with a simulated depth of discharge (DoD) averaging 85% and a simulated energy throughput of 300 kWh per month. The projected remaining battery life, based on this participation, is estimated at 4 years.

In the battery usage analysis summary section, the report 804 provides a summary of the vehicle's energy consumption of 290 kWh per month and the total charge-discharge cycles of 320 cycles per month. This reflects the high intensity of FCR participation and highlights the increased usage the battery undergoes as part of the grid supporting service. Additionally, operational conditions such as temperature and environmental factors are included to provide a summary of battery usage under these conditions.

The battery degradation analysis summary section of the report 804 comprises the impact of frequent deep discharge cycles on the battery's health, with a 12% projected annual capacity loss and a 6% increase in internal resistance. The Depth of Discharge (DoD) averages 85%, contributing significantly to the wear and degradation of the battery. Further, the cycle count is reported as 320 cycles per month, reflecting the high usage due to participation in grid supporting services. In one embodiment, the report further comprises the temperature variations that comprises information about how environmental factors influence battery degradation over time.

The cost-benefit analysis summary section of the report 804 comprises an overview of the financial aspects associated with participation in the grid supporting service. The cost-benefit analysis summary section comprises the financial gains, which are estimated at $250 per month from participating in the Frequency Containment Reserve (FCR) service. The analysis also highlights the battery wear costs, which amount to $80 per month, reflecting the impact of FCR participation on battery degradation. Additionally, the report comprises replacement costs, estimated at $30 per month, accounting for the eventual need to replace the battery due to the wear and tear from service participation. The report comprises the maintenance costs as $20 per month. The report further comprises the net benefit, which is $170 per month, indicating that the financial benefits outweigh the associated costs, making participation in the service financially advantageous for the user.

Based on the summary of the report 804, the user can select whether to continue participating in FCR services by balancing the financial benefits with the impact on battery health. In one embodiment, the report 804 comprises visual elements such as bar charts, graphs, and pie charts.

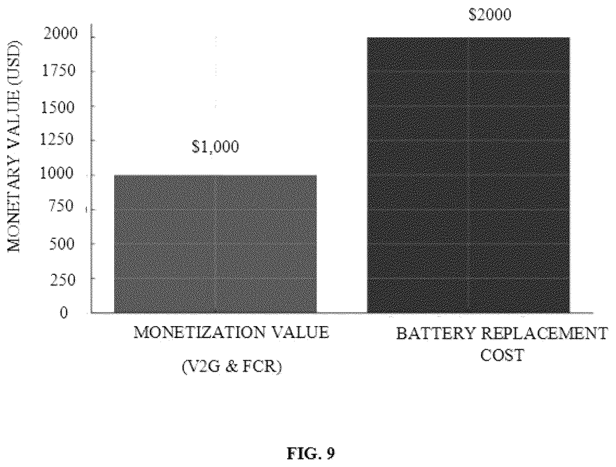

As an example, FIG. 9 illustrates a bar chart comparing monetization value from participation in grid supporting services and battery replacement costs according to one or more embodiments. In this bar chart, the monetization value derived from participation in grid supporting services such as Vehicle-to-Grid (V2G) and Frequency Containment Reserve (FCR) are compared with the battery replacement costs associated with using the vehicle in grid supporting services. The x-axis represents the categories being compared, which are monetization value of V2G and FCR and battery replacement costs. The y-axis displays the monetary value associated with each category. The bar representing monetization value indicates the financial gains the user receives from participating in grid supporting services, while the battery replacement costs bar represents the potential costs for battery replacement after degradation from service participation. The chart enables the user to quickly assess the balance between the financial benefits of participation in grid supporting services and the associated costs for battery replacement. For example, if the vehicle participates in grid supporting services for 6 hours daily over a year, it could generate an estimated $500-$1,000 annually, depending on energy rates and service agreements. Similarly, a typical EV battery replacement might cost $5,000-$7,000, with a prorated cost attributable to grid supporting services amounting to $1,500-$2,000 annually, based on usage and degradation rates.

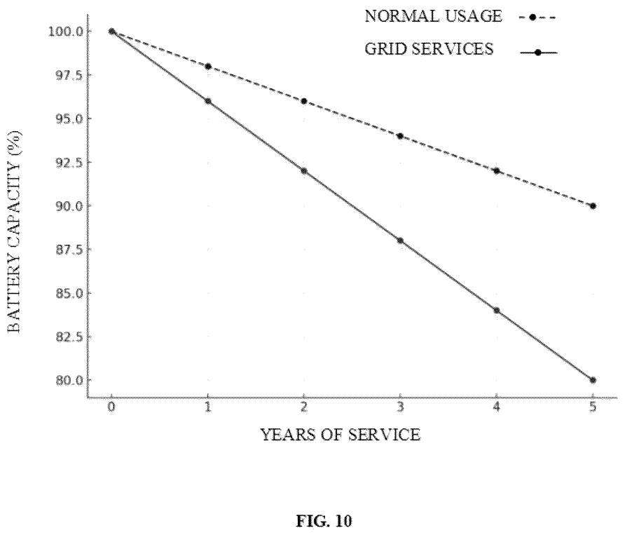

As an example, FIG. 10 illustrates a line graph that depicts progression of battery degradation over time due to participation in grid supporting services, such as V2G or Frequency Containment Reserve (FCR) according to one or embodiments. The x-axis represents the timeline, showing the duration of the participation in grid supporting services (e.g., months or years), and the y-axis shows the level of battery degradation, represented as capacity fade or percentage of original capacity. The line graph illustrates the decline in a battery's energy storage and delivery capacity as it undergoes repeated charge and discharge cycles in the context of grid supporting services. The graph visually illustrates how degradation accelerates over time with frequent service participation, enabling the users to understand the long-term impact on battery health. The line graph also provides insight into the optimal timeframes for battery replacement or further participation in grid supporting services. For example, under normal conditions, a battery might degrade at a rate of 2% annually. However, participation in grid supporting services (e.g., V 2G or FCR), which involves frequent charge and discharge cycles, could increase this degradation rate to 4% annually. After 5 years of participating in the grid supporting service, the battery's capacity might reduce to 80%, compared to 90% without grid participation.

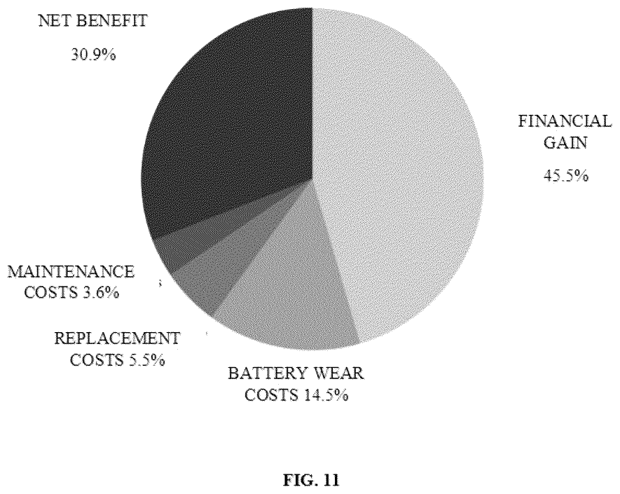

As an example, FIG. 11 illustrates a pie chart depicting the breakdown of the cost-benefit analysis associated with battery usage in grid supporting services according to one or more embodiments. This pie chart illustrates the distribution of costs and financial gains from participation in grid supporting services. The chart breaks down the total financial aspects into different components, comprising financial gains, battery wear costs, replacement costs, maintenance costs, and net benefit. Each segment of the pie is labeled with its corresponding category and the percentage of the total financial impact, providing a visual representation of how each factor contributes to the overall financial outcome.

The pie chart enables the users to quickly assess which factors have the greatest financial influence. For example, if the total financial impact is $1,000, the pie chart shows the following breakdown: financial gains (45.5%, $455), battery wear costs (14.5%, $145), replacement costs (5.5%, $55), maintenance costs (3.6%, $36), and net benefit (30.9%, $309).

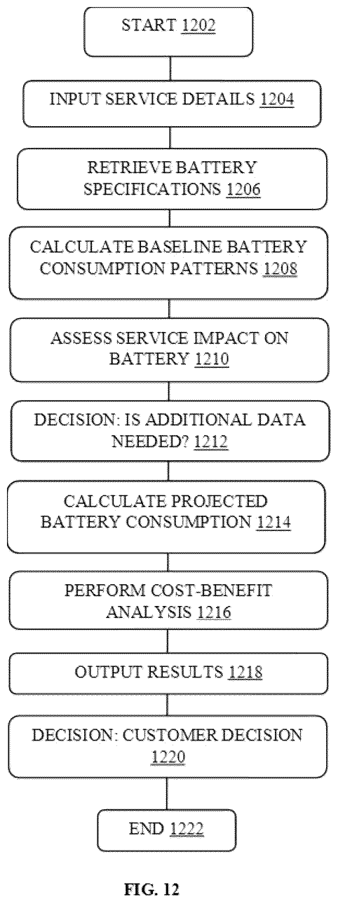

As an example, FIG. 12 illustrates a flowchart that depicts a process for analyzing an impact of grid supporting service participation on a battery of a vehicle according to one or embodiments. At step 1202, the process is initiated, where the system begins the operation of calculating and analyzing the vehicle's participation in grid supporting services. At step 1204, the system receives the first input comprising information on frequency of participation in a Frequency Containment Reserve (FCR) service, expected duration of each session, user-defined preferences and operational parameters related to the battery and the vehicle. At step 1206, the system retrieves the battery specifications, which comprise total capacity, State of Charge (SOC), State of Health (SOH), voltage range, energy efficiency, cycle count, age, model, temperature range, and chemistry type of the battery. In addition, the system retrieves the historical battery usage data corresponding to the battery of a vehicle. At step 1208, the system calculates the one or more baseline battery consumption patterns, which refers to the typical energy usage of the battery under normal conditions, without participating in any grid supporting services. This step enables establishing a base line for comparing the additional impact of grid supporting service participation. At step 1210, the system assesses the impact of the grid supporting service on the battery, considering how different services such as Vehicle-to-Grid (V2G) or Frequency Containment Reserve (FCR) may affect battery consumption and degradation over time. At step 1212, a decision is made whether additional data is needed for the calculation. If further information is required, such as real-time data or specific service performance metrics, the system will collect it before proceeding. At step 1214, the system calculates the projected battery consumption, incorporating the effects of participation in the grid supporting service, such as increased charge and discharge cycles and deeper discharges that may increase the battery wear. At step 1216, a cost-benefit analysis is performed by comparing the financial benefits of participating in the grid supporting services (e.g., energy compensation) against the costs associated with battery degradation, wear, and potential replacement over time. At step 1218, the system outputs the results of the analysis, comprising battery usage, battery degradation, and cost-benefit analysis. These results are then presented as a report to the user. At step 1220, a decision is presented to the user, allowing them to make an informed choice regarding their continued participation in grid supporting services based on the analysis. The user can opt to adjust their service usage or opt out of further participation. At step 1222, the process ends, having completed the evaluation and presented the results to the user, enabling them to decide about their participation in grid supporting services.

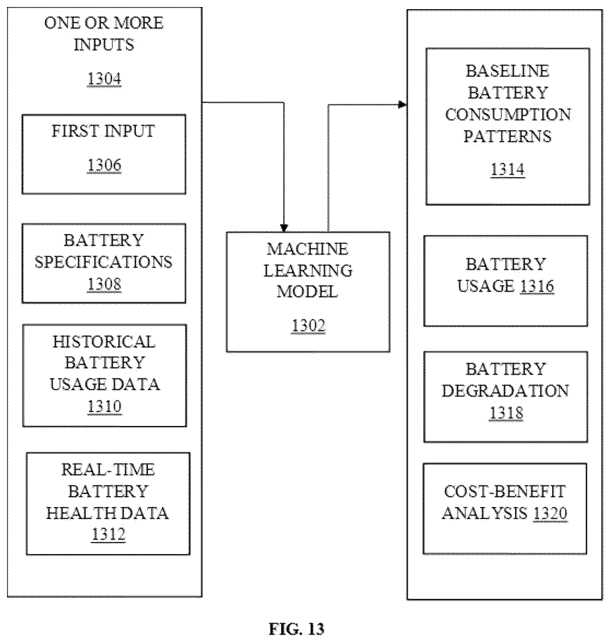

As an example, FIG. 13 illustrates a block diagram of a machine learning model 1302 according to one or more embodiments. The machine learning model 1302 receives one or more inputs 1304 that comprise a first input 1306, battery specifications 1308, historical battery usage data 1310 and real-time battery health data 1312. In one embodiment, the first input 1306 comprises information on frequency of participation in a Frequency Containment Reserve (FCR) service, expected duration of each session, user-defined preferences and operational parameters related to the battery and a vehicle. In one embodiment, the battery specifications 1308 comprise total capacity, State of Charge (SOC), State of Health (SOH), voltage range, energy efficiency, cycle count, age, model, temperature range, and chemistry type of the battery. In one embodiment, the historical battery usage data 1310 comprises charge-discharge cycles, energy throughput, State of Charge (SOC) patterns, environmental factors, charging behavior, load patterns, and battery degradation data.

The system comprises a processor operable to provide a first iteration of training to the machine learning model 1302 based on the one or more inputs 1304. Using the trained machine learning model, the processor determines the baseline battery consumption patterns 1314 which serves as a base line for evaluating the impact of participation in the grid supporting service. The processor then simulates battery performance in relation to the one or more grid supporting services by incorporating change in frequency and intensity of charge and discharge cycles over time based on the baseline battery consumption patterns 1314. For example, if the vehicle participates in a Frequency Containment Reserve (FCR) service, the processor may simulate scenarios where the battery undergoes 200 cycles per month, with an average DoD of 85%. The processor calculates battery usage 1316 and battery degradation 1318 based on the simulation of the battery performance under the one or more grid supporting services.

In one embodiment, the processor incorporates real-world battery chemistry and environmental data into the simulation to improve accuracy. For example, lithium-ion batteries are known to degrade faster under high-temperature conditions or when subjected to frequent deep discharges. The processor considers these variables by integrating temperature profiles, ambient conditions, and specific degradation rates for the battery type in use (e.g., Nickel Manganese Cobalt or Lithium Iron Phosphate chemistries). For example, a 50-kWh battery might experience 12% capacity fade annually when participating in FCR services due to the high intensity of cycles and increased throughput. The system models this degradation and predicts its impact on the battery's remaining life. If the baseline simulation indicates a typical degradation of 8% per year without participating in the grid supporting services, the machine learning model 1302 calculates the additional wear caused by participation in the grid supporting service and calculates the associated costs.

Further, the processor evaluates the cumulative effect of participating in multiple grid supporting services. For example, if the vehicle alternates between V2G services during peak hours and FCR services during off-peak hours, the processor combines these usage profiles to predict aggregated battery degradation and usage patterns. This approach ensures the analysis of the battery's performance across one or more grid supporting services. To further enhance the accuracy of the simulations, the processor utilizes real-time data, such as State of Health (SoH) metrics, to adjust the baseline assumptions dynamically. For example, if real-time data shows that the battery's capacity is lower than expected for its age, the machine learning model 1302 refines the degradation predictions to reflect the battery's current state.

Further, the processor performs, using the machine learning model 1302, a cost-benefit analysis 1320 that corresponds to the one or more grid supporting services by comparing monetization value for participating the vehicle in the one or more grid supporting services with costs associated with at least one of increased wear, replacement, and maintenance of the battery.

The processor continuously receives real-time battery health data 1312 from the battery management system of the vehicle, allowing for dynamic updates to the analysis. The processor further receives an output derived from the simulation of the battery performance under the one or more grid supporting services and the real-time battery health data 1312. These outputs are provided as feedback to the machine learning model 1302 to enable a second iteration of training.

For example, as the EV continues to participate in grid supporting services, the battery management system continuously monitors and provides real-time updates about the battery's health, such as its current state of charge, temperature, and degradation rate. The processor receives this real-time data and combines it with the outputs derived from the battery performance simulation to provide the feedback to the machine learning model 1302. This feedback loop enables the system to refine the simulations and improve accuracy over time. As a result, the machine learning model 1302 can predict the long-term impact of participation in grid supporting service on battery performance. The machine learning model 1302 is then retrained based on the real-time changes, thereby predicting battery usage, degradation, and the associated financial benefits and costs. By continuously updating the machine learning model 1302 with new data, the system can optimize the balance between battery health and maximizing financial returns from participation in grid supporting services. The outputs of the refined model comprise updated battery consumption patterns, battery degradation predictions, and the cost-benefit analysis.

In one embodiment, the outputs from the machine learning model 1302 are displayed to the user via an interactive interface, such as a vehicle infotainment system or a mobile application, to enable informed decisions about the participation in the grid supporting services. The outputs of the processor comprise detailed insights into battery usage and degradation. For example, the processor may predict total energy throughput is 3,600 kWh, capacity loss is 10%, estimated degradation cost is $800, and financial gains from grid supporting services are $3,000. In one embodiment, the processor is further operable to determine the future state of the battery, comprising its health, capacity, and remaining lifespan, under one or more participation scenarios in the grid supporting services, by simulating the battery's response to different frequencies, durations, and intensities of charge and discharge cycles associated with the grid supporting services.

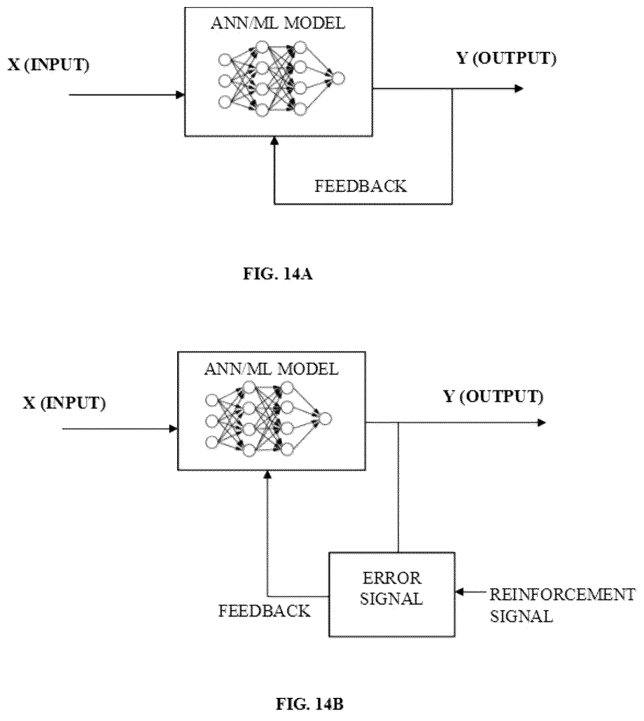

As an example, FIG. 14A shows a structure of the neural network/machine learning model with a feedback loop. Artificial neural networks (ANNs) model comprises an input layer, one or more hidden layers, and an output layer. Each node, or artificial neuron, connects to another and has an associated weight and threshold. If the output of any individual node is above the specified threshold value, that node is activated, sending data to the next layer of the network. Otherwise, no data is passed to the next layer of the network. A machine learning model or an ANN model may be trained on a set of data to take a request in the form of input data, make a prediction on that input data, and then provide a response. The model may learn from the data. Learning can be supervised learning and/or unsupervised learning and may be based on different scenarios and with different datasets. Supervised learning comprises logic using at least one of a decision tree, logistic regression, and support vector machines. Unsupervised learning comprises logic using at least one of a k-means clustering, a hierarchical clustering, a hidden Markov model, and an apriori algorithm. The output layer may communicate a command to the battery management system to perform one of charging and discharging.

In an embodiment, ANNs may be a Deep-Neural Network (DNN), which is a multilayer tandem neural network comprising Artificial Neural Networks (ANN), Convolution Neural Networks (CNN) and Recurrent Neural Networks (RNN). Neural Networks can recognize features from inputs, do an expert review, and perform actions that require predictions, creative thinking, and analytics. In an embodiment, ANNs may be Recurrent Neural Network (RNN), which is a type of Artificial Neural Networks (ANN), which uses sequential data or time series data. Deep learning algorithms are commonly used for ordinal or temporal problems, such as language translation, Natural Language Processing (NLP), speech recognition, and image recognition, etc. Like feedforward and convolutional neural networks (CNNs), recurrent neural networks utilize training data to learn. They are distinguished by their “memory” as they take information from prior input via a feedback loop to influence the current input and output. An output from the output layer in a neural network model is fed back to the model through the feedback (error signal). The variations of weights in the hidden layer(s) will be adjusted to fit the expected outputs better while training the model. This will allow the model to provide results with far fewer mistakes.

The neural network is featured with the feedback loop to adjust the system output dynamically as it learns from the new data. In machine learning, backpropagation and feedback loops are used to train an Artificial Intelligence (AI) model and continuously improve it upon usage. As the incoming data that the model receives increases, there are more opportunities for the model to learn from the data. The feedback loops, or backpropagation algorithms, identify inconsistencies and feed the corrected information back into the model as an input.

Even though the Artificial Intelligence/Machine Learning (AI/ML) model is trained well, with large sets of labeled data and concepts, after a while, the models'performance may decline while adding new, unlabeled input due to many reasons which include, but not limited to, concept drift, recall precision degradation due to drifting away from true positives, and data drift over time. A feedback loop in the model keeps the AI results accurate and ensures that the model maintains its performance and improvement, even when new unlabeled data is assimilated. A feedback loop refers to the process by which an AI model's predicted output is reused to train new versions of the model.

Initially, when the AI/ML model is trained, a few labeled samples comprising both positive and negative examples of the concepts (for e.g., calculating battery usage and battery degradation caused by participation in grid supporting services and performing cost-benefit analysis, etc.) are used that are meant for the model to learn. Afterward, the model is tested using unlabeled data. By using, for example, deep learning and neural networks, the model can then make predictions on whether the desired concept/s (for e.g., calculating battery usage and battery degradation caused by participation in grid supporting services and performing cost-benefit analysis, etc.) are in unlabeled images. Each image is given a probability score where higher scores represent a higher level of confidence in the models'predictions. Where a model gives an image a high probability score, it is auto labeled with the predicted concept. However, in the cases where the model returns a low probability score, this input may be sent to a controller (may be a human moderator) which verifies and, as necessary, corrects the result. The human moderator may be used only in exception cases. The feedback loop feeds labeled data, auto labeled or controller-verified, back to the model dynamically and is used as training data so that the system can improve its predictions in real-time and dynamically.

As an Example, FIG. 14B shows a structure of the neural network/machine learning model with reinforcement learning. The network receives feedback from authorized networked environments. Though the system is similar to supervised learning, the feedback obtained in this case is evaluative not instructive, which means there is no teacher as in supervised learning. After receiving the feedback, the network performs adjustments of the weights to get better predictions in the future. Machine learning techniques, like deep learning, allow models to take labeled training data and learn to recognize those concepts in subsequent data and images. The model may be fed with new data for testing, hence by feeding the model with data it has already predicted over, the training gets reinforced. If the machine learning model has a feedback loop, the learning is further reinforced with a reward for each true positive of the output of the system. Feedback loops ensure that AI results do not stagnate. By incorporating a feedback loop, the model output keeps improving dynamically and over usage/time.

In an embodiment, icons on a graphical user interface (GUI) or display of the infotainment system of a computer system are re-arranged based on a priority score of the content of the message. The processor tracks the messages that need to be displayed at a given time and generates a priority score, wherein the priority score is determined based on the action that needs to be taken by the user, the time available before the user input is needed, content of the message to be displayed, criticality of the user's input/action that needs to be taken, the sequence of the message or messages that need to be displayed and executed, and the safety of the overall scenario. For example, in case of a health emergency, the messages in queue for displaying could be an emergency signal, type of emergency, intimation that an alert is provided to the nearby vehicles, instructing a path for the driver to pull over, calling the emergency services, etc. In all these messages that need a driver's attention, a priority score is provided based on the actions that need to be taken by the user, the time available for the user to receive the displayed message and react with an action, the content of the message, criticality of the user's input/action, sequence of the messages that need to be executed, and safety of the overall scenario. Considering the above example, the message that intimates the user/driver that an alert has been provided to nearby vehicles may be of lower priority as compared to instructing the path for the driver to pull over. Therefore, the pull over directions for the path message takes priority and takes such a place on the display (example, center of the display) which can grab the users'attention immediately. The priority of the messages is evaluated dynamically as the situation is evolving and thus the display icons, positions, and sizes of the text or icon on the display are changed in real-time and dynamically. In an embodiment, more than one message is displayed and highlighted as per the situation and the user's actions. Further, while pulling over, if an unsafe scenario is found, for example, a vehicle is changing lanes which may obstruct the user's vehicle, the message dynamically changes and warns the driver about the developing scenario. In another scenario of a vehicle with charge less than threshold charge level, the processor dynamically reassigns the priority score and depicts nearby charging station and navigates the route to the charging station onto a display in the dashboard.

In an embodiment, the system further comprises a cyber security module wherein the cyber security module comprises an information security management module providing isolation between the communication module and servers.

In an embodiment, the information security management module is operable to, receive data from the communication module, exchange a security key at a start of the communication between the communication module and the server, receive the security key from the server, authenticate an identity of the server by verifying the security key, analyze the security key for a potential cyber security threat, negotiate an encryption key between the communication module and the server, encrypt the data; and transmit the encrypted data to the server when no cyber security threat is detected.

In an embodiment, the information security management module is operable to exchange a security key at a start of the communication between the communication module and the server, receive the security key from the server, authenticate an identity of the server by verifying the security key, analyze the security key for a potential cyber security threat, negotiate an encryption key between the system and the server, receive encrypted data from the server, decrypt the encrypted data, perform an integrity check of the decrypted data and transmit the decrypted data to the communication module when no cyber security threat is detected.

In an embodiment, the system may comprise a cyber security module.

In one aspect, a secure communication management (SCM) computer device for providing secure data connections is provided. The SCM computer device includes a processor in communication with memory. The processor is programmed to receive, from a first device, a first data message. The first data message is in a standardized data format. The processor is also programmed to analyze the first data message for potential cyber security threats. If the determination is that the first data message does not contain a cyber security threat, the processor is further programmed to convert the first data message into a first data format associated with the vehicle environment and transmit the converted first data message to the vehicle system using a first communication protocol associated with the vehicle system.

According to an embodiment, secure authentication for data transmissions comprises, provisioning a hardware-based security engine (HSE) located in the information security management module, said HSE having been manufactured in a secure environment and certified in said secure environment as part of an approved network; performing asynchronous authentication, validation and encryption of data using said HSE, storing user permissions data and connection status data in an access control list used to define allowable data communications paths of said approved network, enabling communications of the communications system with other computing system subjects to said access control list, performing asynchronous validation and encryption of data using security engine including identifying a user device (UD) that incorporates credentials embodied in hardware using a hardware-based module provisioned with one or more security aspects for securing the system, wherein security aspects comprising said hardware-based module communicating with a user of said user device and said HSE.

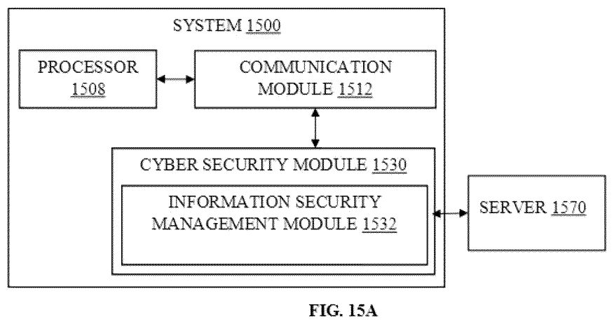

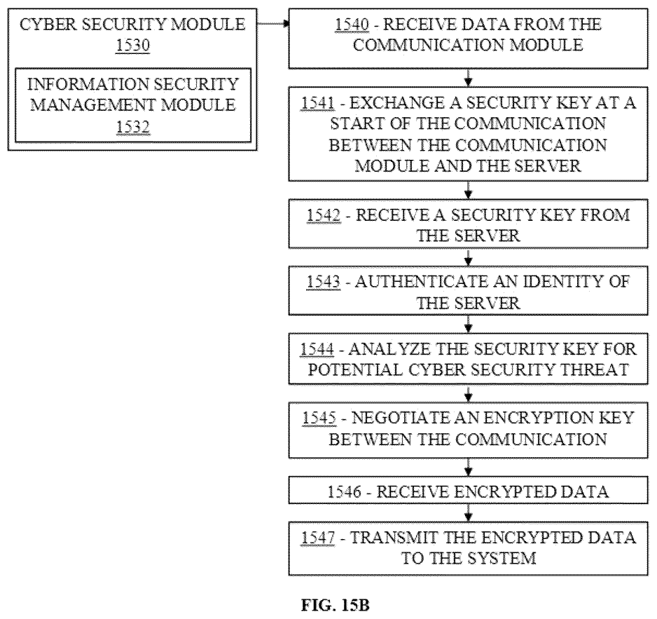

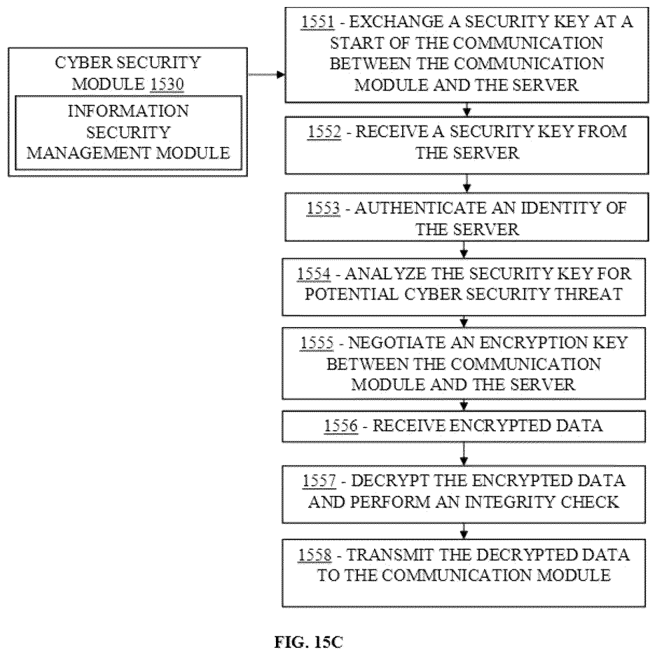

In an embodiment, FIG. 15A shows the block diagram of the cyber security module. The communication of data between the system 1500 and the server 1570, through the processor 1508, through the communication module 1512, is first verified by the information security management module 1532 before being transmitted from the system to the server or from the server to the system. The information security management module is operable to analyze the data for potential cyber security threats, to encrypt the data when no cyber security threat is detected, and to transmit the data encrypted to the system or the server.

In an embodiment, the cyber security module further comprises an information security management module providing isolation between the system and the server. FIG. 15B shows the flowchart of securing the data through the cyber security module 1530. At step 1540, the information security management module 1532 is operable to receive data from the communication module. At step 1541, the information security management module exchanges a security key at a start of the communication between the communication module and the server. At step 1542, the information security management module receives a security key from the server. At step 1543, the information security management module authenticates an identity of the server by verifying the security key. At step 1544, the information security management module analyzes the security key for potential cyber security threats. At step 1545, the information security management module negotiates an encryption key between the communication module and the server. At step 1546, the information security management module receives the encrypted data. At step 1547, the information security management module transmits the encrypted data to the server when no cyber security threat is detected.

In an embodiment, FIG. 15C shows the flowchart of securing the data through the cyber security module 1530. At step 1551, the information security management module 1532 is operable to: exchange a security key at a start of the communication between the communication module and the server. At step 1552, the information security management module receives a security key from the server. At step 1553, the information security management module authenticates an identity of the server by verifying the security key. At step 1554, the information security management module analyzes the security key for potential cyber security threats. At step 1555, the information security management module negotiates an encryption key between the communication module and the server. At step 1556, the information security management module receives encrypted data. At step 1557, the information security management module decrypts the encrypted data, and performs an integrity check of the decrypted data. At step 1558, the information security management module transmits the decrypted data to the communication module when no cyber security threat is detected.

In an embodiment, the integrity check is a hash-signature verification using a Secure Hash Algorithm 256 (SHA256) or a similar method.

In an embodiment, the information security management module is configured to perform asynchronous authentication and validation of the communication between the communication module and the server.

In an embodiment, the information security management module is configured to raise an alarm if a cyber security threat is detected. In an embodiment, the information security management module is configured to discard the encrypted data received if the integrity check of the encrypted data fails.

In an embodiment, the information security management module is configured to check the integrity of the decrypted data by checking accuracy, consistency, and any possible data loss during the communication through the communication module.

In an embodiment, the server is physically isolated from the system through the information security management module. When the system communicates with the server as shown in FIG. 15A, identity authentication is first carried out on the system and the server. The system is responsible for communicating/exchanging a public key of the system and a signature of the public key with the server. The public key of the system and the signature of the public key are sent to the information security management module. The information security management module decrypts the signature and verifies whether the decrypted public key is consistent with the received original public key or not. If the decrypted public key is verified, the identity authentication is passed. Similarly, the system and the server carry out identity authentication on the information security management module. After the identity authentication is passed on to the information security management module, the two communication parties, the system, and the server, negotiate an encryption key and an integrity check key for data communication of the two communication parties through the authenticated asymmetric key. A session ID number is transmitted in the identity authentication process, so that the key needs to be bound with the session ID number; when the system sends data to the outside, the information security gateway receives the data through the communication module, performs integrity authentication on the data, then encrypts the data through a negotiated secret key, and finally transmits the data to the server through the communication module. When the information security management module receives data through the communication module, the data is decrypted first, integrity verification is carried out on the data after decryption, and if verification is passed, the data is sent out through the communication module; otherwise, the data is discarded.

In an embodiment, the identity authentication is realized by adopting an asymmetric key with a signature.

In an embodiment, the signature is realized by a pair of asymmetric keys which are trusted by the information security management module and the system, wherein the private key is used for signing the identities of the two communication parties, and the public key is used for verifying that the identities of the two communication parties are signed. Signing identity comprises a public and a private key pair. In other words, signing identity is referred to as the common name of the certificates which are installed in the user's machine.

In an embodiment, both communication parties need to authenticate their own identities through a pair of asymmetric keys, and a task in charge of communication with the information security management module of the system is identified by a unique pair of asymmetric keys.

In an embodiment, the dynamic negotiation key is encrypted by adopting a Rivest-Shamir-Adleman (RSA) encryption algorithm. RSA is a public key cryptosystem that is widely used for secure data transmission. The negotiated keys include a data encryption key and a data integrity check key.

In an embodiment, the data encryption method is a Triple Data Encryption Algorithm (3DES) encryption algorithm. The integrity check algorithm is a Hash-based Message Authentication Code (HMAC-MD5-128) algorithm. When data is output, the integrity check calculation is carried out on the data, the calculated Message Authentication Code (MAC) value is added with the header of the value data message, then the data (including the MAC of the header) is encrypted by using a 3DES algorithm, the header information of a security layer is added after the data is encrypted, and then the data is sent to the next layer for processing. In an embodiment the next layer refers to a transport layer in the Transmission Control Protocol/Internet Protocol (TCP/IP) model.

The information security management module ensures the safety, reliability, and confidentiality of the communication between the system and the server through the identity authentication when the communication between the two communication parties starts the data encryption and the data integrity authentication. The method is particularly suitable for an embedded platform which has less resources and is not connected with a Public Key Infrastructure (PKI) system and can ensure that the safety of the data on the server cannot be compromised by a hacker attack under the condition of the Internet by ensuring the safety and reliability of the communication between the system and the server.

Other specific forms may embody the present invention without departing from its spirit or characteristics. The described embodiments are in all respects illustrative and not restrictive. Therefore, the appended claims rather than the description herein indicate the scope of the disclosure. All variations which come within the meaning and range of equivalency of the claims are within their scope.

1-68. (canceled)

69. A system comprising:
a memory; and
a processor that is communicatively coupled to the memory, wherein the processor is operable to:
receive a first input comprising information on one or more grid supporting services;
retrieve battery specifications of a battery and historical battery usage data corresponding to the battery of a vehicle;
determine one or more baseline battery consumption patterns based on the first input, the battery specifications, and the historical battery usage data;
simulate battery performance in relation to the one or more grid supporting services by incorporating change in frequency and intensity of charge and discharge cycles over time based on the one or more baseline battery consumption patterns;
calculate battery usage and battery degradation during the simulation of the battery performance under the one or more grid supporting services; and
generate a report upon calculating the battery usage and the battery degradation.

70. The system of claim 69, wherein the one or more grid supporting services are selected from at least one of a Vehicle-to-Grid (V2G) service and a Frequency Containment Reserve (FCR) service.

71. The system of claim 69, wherein the processor is operable to calculate the battery usage by performing a battery usage analysis that comprises determining energy throughput, charge and discharge cycles, depth of discharge (DoD), and operational conditions of the battery during participation in the one or more grid supporting services.

72. The system of claim 69, wherein the processor is operable to calculate the battery degradation by performing a battery degradation analysis that comprises determining capacity fade, internal resistance growth, depth of discharge, charge and discharge cycle count, and temperature variations over time of the battery during operation under the one or more grid supporting services.

73. The system of claim 69, wherein the one or more baseline battery consumption patterns are determined using a machine learning model.

74. The system of claim 69, wherein the processor is operable to determine a range of one or more inputs that comprise the first input, the battery specifications, and the historical battery usage data and determine that the range of the one or more inputs is in a predefined range.

75. The system of claim 74, wherein the predefined range is dynamically adjusted based on characteristics of the one or more inputs being analyzed.

76. The system of claim 75, wherein the characteristics of the one or more inputs comprises a source of the one or more inputs and historical patterns of previous analysis of the battery performance to enhance accuracy of determining the range of the one or more inputs.

77. The system of claim 74, wherein the processor is operable to provide a first iteration of training to a machine learning model based on the one or more inputs.

78. The system of claim 69, wherein the processor is operable to perform, using a machine learning model, a cost-benefit analysis that corresponds to the one or more grid supporting services by comparing monetization value of participating the vehicle in the one or more grid supporting services with costs associated with at least one of increased wear, replacement, and maintenance of the battery.

79. The system of claim 78, wherein the processor is operable to generate the report based on the simulation of battery performance, a battery usage analysis, a battery degradation analysis and the cost-benefit analysis corresponding to the one or more grid supporting services.

80. The system of claim 79, wherein the report comprises a summary of the battery usage analysis, the battery degradation analysis, and the cost-benefit analysis corresponding to the one or more grid supporting services.

81. A method comprising:
receiving a first input comprising information on one or more grid supporting services;
retrieving battery specifications of a battery and historical battery usage data corresponding to the battery of a vehicle;
determining one or more baseline battery consumption patterns based on the first input, the battery specifications, and the historical battery usage data;
simulating battery performance in relation to the one or more grid supporting services by incorporating change in frequency and intensity of charge and discharge cycles over time based on the one or more baseline battery consumption patterns;
calculating battery usage and battery degradation during the simulation of the battery performance under the one or more grid supporting services; and
generating a report upon calculating the battery usage and the battery degradation.

82. The method of claim 81, further comprising: displaying the report corresponding to the one or more grid supporting services to a user.

83. The method of claim 82, further comprising: receiving a feedback from the user in response to the displayed report.

84. The method of claim 83, further comprising: modifying the simulation of the battery performance based on the feedback received from the user.

85. A non-transitory computer readable storage medium comprising a sequence of instructions, which when executed by a processor causes:
receiving a first input comprising information on one or more grid supporting services;
retrieving battery specifications of a battery and historical battery usage data corresponding to the battery of a vehicle;
determining one or more baseline battery consumption patterns based on the first input, the battery specifications, and the historical battery usage data;
simulating battery performance in relation to the one or more grid supporting services by incorporating change in frequency and intensity of charge and discharge cycles over time based on the one or more baseline battery consumption patterns;
calculating battery usage and battery degradation during the simulation of the battery performance under the one or more grid supporting services; and
generating a report upon calculating the battery usage and the battery degradation.

86. The non-transitory computer readable storage medium of claim 85, further comprising: continuously receiving real-time battery health data from a battery management system of the vehicle.

87. The non-transitory computer readable storage medium of claim 86, further comprising: receiving an output derived from the simulation of the battery performance under the one or more grid supporting services and the real-time battery health data and providing the output as a feedback to a machine learning model to provide a second iteration of training.

88. The non-transitory computer readable storage medium of claim 87, wherein the machine learning model refines the calculation of the battery usage, and the battery degradation based on the second iteration of training.
